(19) United States
(12) Patent Application Publication
(10) Pub. No.: US 2010/0230696 A1
(43) Pub. Date: Sep. 16, 2010

(54) WIRING MEMBER, METAL COMPONENT WITH RESIN AND RESIN SEALED SEMICONDUCTOR DEVICE, AND PROCESSES FOR PRODUCING THEM

(76) Inventor: Takahiro Fukunaga, Kyoto (JP)

Correspondence Address: SNELL & WILMER L.L.P. (Panasonic), 600 ANTON BOULEVARD, SUITE 1400, COSTA MESA, CA, 92626, US

(21) Appl. No.: 12/672,876

(22) PCT Filed: Aug. 21, 2008
(86) PCT No.: PCT/JP2008/002258

§ 371 Date: May 13, 2010

(30) Foreign Application Priority Data
Aug. 29, 2007 (JP) 2007-222052

(51) Int. Cl. H01L 23/31; H01L 21/60; H01L 33/52; H01L 23/48; H01L 21/56; H01B 3/30

(52) U.S. Cl. 257/98; 438/124; 257/692; 174/110 R; 174/110 SR; 257/E23.01; 257/E23.127; 257/E33.056; 257/E33.067; 257/E21.506; 257/E21.502

(57) ABSTRACT

There is provided a semiconductor device that suppresses the occurrence of resin burrs to ensure favorable electrical connectivity and bond strength, and a manufacturing method for such semiconductor device. Also provided is an LED device which ensures stronger adhesion between a silicone resin and a wiring lead and thus achieves favorable light emitting properties, and a manufacturing method for such LED device. Also provided is an LED device that can present superior luminous efficiency by the provision of a sufficient reflectivity even when emitting relatively short wavelength light, and a manufacturing method for such LED device. Also provided is a film carrier tape with which a superior Sn plating coat is formed, mechanical strength and connectivity are achieved. Also provided is a manufacturing method for such film carrier tape that can avoid damage to the wiring pattern layer during an Sn plating step while maintaining favorable manufacturing efficiency. Specifically, an organic coat 110 is provided on a surface of an outer lead 301a of a QFP 10 at a location close to the border region. The organic coating 110 is formed by self-assembling functional organic molecules 11. Each of the functional organic molecules 11 includes a first functional group A1 having a metal bonding property, a main chain B1, and a second functional group C1 having a resin hardening property or a resin-hardening promoting property.

### TECHNICAL FIELD

The present invention relates to a wiring member, a resin-coated metal part and a resin-sealed semiconductor device, and a manufacturing method for the resin-coated metal part and the resin-sealed semiconductor device, and in particular to technology for improving adhesion between a metallic material and a resin material.

### BACKGROUND ART

Resin materials are widely used in semiconductor devices and wiring members.

In general, a semiconductor device such as an integrated circuit (IC) or large scale integrated circuit (LSI) are manufactured by a process in which a predetermined semiconductor element is connected to wiring leads by wire bonding etc., a portion of the wiring leads are exposed to the exterior, and packaging by resin sealing is performed by adhering resin to the wiring leads in this condition.

FIG. 22 are schematic cross-sectional diagrams showing manufacturing steps for a resin-sealed QFP (Quad Flat Package) semiconductor device.

First, a semiconductor chip 94 is mounted on a die pad 93b of a wiring lead 93 (including die pads 93a and 93b), and the semiconductor chip 94 and the die pads 93a and 93b are connected by a wire 95.

Thereafter, the wiring lead 93 is disposed on a fixed die 92 (FIG. 22A).

Next, a movable die 91 is pressed on the fixed die 92 such that the dies 91 and 92 are closed together to form an inner space (cavity 97) therebetween. A thermosetting resin is injected into the cavity 97 via a gate 96 provided in the movable die 91, thereby resin-sealing the semiconductor chip 94 etc. (FIG. 22B).

After hardening the thermosetting resin to form a molded resin 98, the dies 91 and 92 are opened, and an ejector pin (not depicted) is used to press out a resin cast 9z.

Then outer leads 931a of the resin cast are bent, thereby obtaining a completed semiconductor device 9 (FIG. 22D).

The above were exemplary manufacturing steps for a QFP semiconductor device. There are other types of semiconductor devices, such as a light emitting diode (LED) device. An LED device is manufactured by, for example, forming a substrate in the interior of a bowl-shaped reflector such that a portion of a wiring lead is exposed, and mounting an LED element on the wiring lead in the reflector to connect the LED element and the wiring lead, and thereafter filling the interior of the reflector with a transparent sealing resin. In place of epoxy resin, silicone resin with a higher light transmittance is currently becoming more widely used.

Furthermore, film carrier tape, examples of which are TAB (Tape Automated Bonding) tape, T-BGA (Tape Ball Grid Array) tape, and ASIC (Application Specific Integrated Circuit) tape, and which is used in the implementation of electrical parts of the IC, LSI, etc., has a structure in which an insulating film composed of a polyimide etc., a wiring pattern layer composed of Cu, and a solder resist layer are laminated in the stated order. Here, resin materials are used as the insulating film and the solder resist layer.

Patent document 1: Japanese Patent No. 2731123

Patent document 2: Japanese Patent Application Publication No. H10-329461

Patent document 3: Japanese Patent Application Publication No. 2002-33345

Patent document 4: Japanese Patent No. 3076342

### SUMMARY OF INVENTION

### Technical Problem

However, resin casts in semiconductor devices and LED devices, as well as film carrier tape have the following issues.

The first issue is a problem in which during the injection of the sealing resin to form an intended resin mold, the resin adheres to unintended regions of a wiring lead that are not intended. As shown in the enlarged portion P of FIG. 22B in the manufacturing steps for the semiconductor device, there is the possibility that due to the injection of the resin material at a constant pressure, resin thin films (so called resin burrs) are formed on surfaces of the outer leads 931a of the wiring lead 93 when the resin material flows into gaps 900 between the dies (FIG. 22C). These gaps 900 occur due to imprecision between the dies 91 and 92, and the resin burrs 98a are formed due to the outflow of the resin material that occurs when the pressure during injection becomes directed into the gaps 900. The existence of the resin burrs 98a makes it possible for there to be problems with the connection strength and electric contact between the outer leads 931a and a substrate 99 in the next step. Although the dies 91 and 92 may be shaped with higher precision in order to prevent this problem, not only do costs rises significantly due to die designing, but also it is very difficult to completely prevent the occurrence of gaps due to problems with machine precision. In practice, it is assumed that the occurrences of resin burrs cannot be prevented, which requires an additional step of removing the resin burrs 98a before the step for connection with the substrate. This leads to a problem of a decrease in manufacturing efficiency and a rise in manufacturing costs.

Patent documents 1 to 3 for example propose measures for preventing space or gap (s) between the metal dies. However, the technology disclosed in patent documents 1 and 2 increases the pressure applied to the wiring lead of the dies, and therefore there is the danger of applying an excessive deforming stress to the wiring lead, and there is the fear of damaging the dies or the wiring lead. Patent document 3 discloses technology for improving closure of the dies by pre-adhering tape to portions of the dies where the gaps occur. However, even if such tape is used, there is the possibility of problems such as detachment of and damage to the tape in the injection step which involves mechanical frictional force under relatively high temperatures. Moreover, providing the tape still has problems with respect to a decrease in manufacturing efficiency and a rise in manufacturing costs.

Additionally, there is another problem regarding insufficient adhesion between a wiring lead and a sealing resin. FIG. 23 are cross-sectional views illustrating the problems noted above. In general, a sealing resin (molded resin 98) tends to be infiltrated with water under the influence of ambient humidity. If the adhesion of the sealing resin (molded resin 98) with the wiring leads 93a and 93b is insufficient, there will be slight gaps between the facing surfaces (FIG. 23A). The water infiltrated into the resin gradually accumulates in the gaps. At the time when the semiconductor device 9 is implemented onto the substrate 99, the accumulated water evaporates and undergoes rapid volume expansion due to reflow heat of solder 90. As a result, there is a risk of pealing at the gaps and of cracks in the molded resin 98 (FIG. 23B). Such pealing and cracks likely to invite the infiltration of more impurities, such as water, into the semiconductor device 9 from outside. This may become a cause of problems that reduces the reliability of sealing, such as rupturing or shorting of a circuit of the semiconductor chip 94.

Even if a serious breaking as described above does not occur at the time of reflow, water accumulated in the gaps may eventually cause shorting in the semiconductor chip 94 and result in operation failure.

The second issue is a problem when using silicone resin to seal an LED chip in an LED device. Although able to maintain a high transparency, silicone resin has a higher linear expansion coefficient than epoxy resin etc. There is therefore the possibility that the silicone resin will heat-shrink due to thermal change (so-called thermal history) in the resin material in the step for injecting the silicone resin on the substrate. Accordingly, there is detachment between the silicone resin and the wiring lead, and there is the possibility of problems such as performance degradation due to poor contact, or insufficient contact strength. In addition, when a addition silicone resin which is highly transparent is used, a platinum group catalyst required for the addition polymerization may cause discoloring of a highly reflective Ag plating coat. Further, since the silicone resin has high gas permeability, there is a risk that the Ag plating coat to cause discoloring of the Ag plating coat.

The third issue is a problem relates to an Ag plating coat provided on surfaces of the wiring lead in order to improve luminous efficiency in an LED device. Although known to have a high reflectivity with respect to long wavelength visible light, Ag materials have a comparatively low reflectivity with respect to short wavelength light (approximately 500 nm or below). Accordingly, a sufficient reflectivity cannot be obtained when a blue, violet, ultraviolet, LED etc. is implemented in an LED device, in which case there may be the possibility of not obtaining an intended luminous efficiency.

Further, in the case where an Ag plating coat is provided to coat a reflector formed to surround an LED chip of an LED device, unnecessary gas produced in the manufacturing process may adhere to the surface of Ag plating coat to cause alteration of Ag. As a result of such alteration, the Ag plating coat will be no longer able to provide the intended reflectivity, which causes the risk of decrease in the luminous efficiency of the LED device.

Further, in the case where the reflector is made of a material such as a thermoplastic resin, gas released from the material (hereinafter, “outgas”) adheres to a lead wire to cause failure of wire bonding. That is, the presence of the outgas reduces the strength of the proper bonding between the wiring lead and the wire, which leads to a problem so-called “non-bonding of wires”. Examples of non-bonding of wires include bonding error and wire detachment.

The fourth issue is a problem in a case of providing an Sn plating coat on the wiring pattern layer in the film carrier tape.

An Sn coating layer is provided on the surface of the wiring pattern layer in order for connection with implementation parts by soldering. The ends of the solder resist layer peel due to the heated atmosphere in the plating step, and localized batteries are formed between an area under the peeled solder resist layer and another area on the surface of the wiring pattern layer due to the difference in ionization tendency of Sn ions and Cu ions (FIG. 24A). As a result of the formation of the localized batteries, erosion areas are formed due to Cu ions that have eluted into the surface of the wiring pattern layer. There is therefore the possibility of problems with respect to a reduction in the mechanical strength of the film carrier tape after the Sn plating coat has been performed, and with respect to the plating coat not being formed evenly.

As mentioned above, it can be said that there are still matters to be resolved when using resin materials in the fields of semiconductor devices and film carrier tape.

The present invention has been made in light of the above issues, and a first aim thereof is to provide a semiconductor device and a manufacturing method for the semiconductor device having favorable electrical connectivity, bond strength and sealing reliably, by suppressing the occurrence of resin burrs, detachment of the resin from the wiring lead, occurrence of cracks in the resin, and the like.

A second aim of the present invention is to provide an LED device that can achieve favorable light emitting properties and a manufacturing method for such LED device, by suppressing the occurrences of various problems, including alteration and discoloring of component elements, degrease of luminous efficiency, and non-bonding of wires, while improving the adhesion between silicone resin and wiring leads.

A third aim of the present invention is to provide an LED device that can present superior luminous efficiency by the provision of a sufficient reflectivity even when emitting relatively short wavelength light, and a manufacturing method for such LED device.

A fourth aim of the present invention is to provide a film carrier tape that has superior Sn plating layer formation, mechanical strength, and connectivity, and a manufacturing method for such film carrier tape that can avoid damage to the wiring pattern layer during an Sn plating step while maintaining favorable manufacturing efficiency.

### Solution to Problem

In order to solve the aforementioned problems, a first aspect of the present invention provides a manufacturing method for a resin-coated metal part. The method includes the steps of: forming an organic coating by (i) depositing a material containing a plurality of functional organic molecules on a wiring lead composed of a metallic material, each of the functional organic molecules having a main chain, a first functional group having a metal bonding property, and a second functional group having a predetermined property, the first functional group and the second functional group each being provided at a different end of the main chain, and (ii) causing the plurality of functional organic molecules to self-assemble by bonding of the first functional groups to metal atoms of the wiring lead; and adhering a resin to a predetermined surface region of the wiring lead having the organic coating formed thereon, the adhering step being performed after the organic coating formation step. Each of the functional organic molecules used in the organic coating formation step has the main chain composed of at least one selected from the group consisting of a methylene chain, a fluoromethylene chain, a siloxane chain, and a glycol chain.

Here, the first functional group of each of the functional organic molecules may be a compound, a chemical structure, or a derivative having at least one selected from the group consisting of a thiol compound, a sulfide compound, and a nitrogen-containing heterocyclic compound.

Here, the resin may be a thermosetting resin.

Here, the thermosetting resin may be a compound, a chemical structure, or a derivative having at least one selected from the group consisting of an epoxy resin, a phenol resin, an acryl resin, a melamine resin, a urea resin, an unsaturated polyester resin, an alkyd resin, a polyimide resin, a polyamide resin, and a polyether resin. Each second functional group my be a compound, a chemical structure, or a derivative having at least one selected from the group consisting of a hydroxyl, a carboxylic acid, an acid anhydride, a primary amine, a secondary amine, a tertiary amine, an amide, a thiol, a sulfide, an imide, a hydrazide, an imidazole, a diazabicyclo-alkene, an organic phosphine, and a boron trifluoride amine complex.

Here, in the organic coating formation step, the organic coating may be formed to cover a surface region of the wiring lead that is greater in area than the predetermined surface region of the wiring lead where the resin is to be adhered in the resin adhering step.

Here, the thermosetting resin may be a silicone resin or a silicone resin having at least either of an epoxy group and an alkoxysilyl group. Each second functional group may be a compound, a chemical structure, or a derivative having at least one selected from the group consisting of a vinyl group, an organohydrogensilane, a hydroxyl, an acid anhydride, a primary amine, and a secondary amine.

Here, the thermosetting resin may be a silicone resin. Each second functional group may be a compound, a chemical structure, or a derivative having at least one selected from the group consisting of platinum, palladium, ruthenium, and rhodium. Note that the silicone resin may also be a silicone resin-containing conductive paste (a die bonding agent).

Here, each second functional group may be a compound, a chemical structure, or a derivative having at least one selected from the group consisting of a fluorescent compound and a phosphorescent compound.

Another aspect of the present invention provides a manufacturing method for a resin-coated metal part. The manufacturing method includes the steps of: forming an organic coating by (i) depositing a material containing a plurality of functional organic molecules on a wiring lead composed of a metallic material, each of the functional organic molecules having a main chain, a first functional group having a metal bonding property, and a second functional group having a predetermined property, the first functional group and the second functional group each being provided at a different end of the main chain, and (ii) causing the plurality of functional organic molecules to self-assemble by bonding of the first functional groups to metal atoms of the wiring lead; and adhering a thermosetting resin to a predetermined surface region of the wiring lead having the organic coating formed thereon, the adhering step being performed after the organic coating formation step. The thermosetting resin is a silicone resin or a silicone resin having at least either of an epoxy group and an alkoxysilyl group. Each second functional group is a compound, a chemical structure, or a derivative having at least one selected from the group consisting of a vinyl group, an organohydrogensilane, a hydroxyl, an acid anhydride, a primary amine, and a secondary amine.

Here, in the organic coating formation step, the main chain of each functional organic molecules may be at least one selected from the group consisting of a methylene chain, a fluoromethylene chain, and a siloxane chain. Each first functional group may be a compound, a chemical structure, or a derivative having at least one selected from the group consisting of a thiol compound, a sulfide compound, and a nitrogen-containing heterocyclic compound.

Here, the organic coating formation step may include the substeps of: preparing an organic molecule dispersion fluid by dispersing the plurality of functional organic molecules in a solvent; and immersing the wiring lead in the organic molecule dispersion fluid so that an immersed surface region of the wiring lead is greater in area than the predetermined surface region of the wiring lead where the resin is to be adhered.

Another aspect of the present invention provides a method including: the steps of any of the resin-coated metal part manufacturing methods according to the present invention; and the step of electrically connecting the wiring lead to a semiconductor element. The connecting step is performed between the organic coating formation step and the resin adhering step. In the resin adhering step, the resin is molded so that the semiconductor element is encapsulated in the resin and that a portion of the wiring lead is externally exposed.

A yet another aspect of the present invention provides a wiring member including: a wiring lead composed of a metallic material; and an organic coating disposed to cover a surface region of the wiring lead, the organic coating being composed of a plurality of self-assembled functional organic molecules. Each of the functional organic molecules has a chemical structure having a main chain, a first functional group, and a second functional group. Each of the first functional group and the second functional group is provided at a different end of the main chain. The first functional group is in a form for bonding to the wiring lead by any one or more of a metal bond, a hydrogen bond, and a coordinate bond by a metal complex. The second functional group has a resin hardening property or a resin-hardening promoting property. The main chain of each of the functional organic molecules is (i) a glycol chain or (ii) a glycol chain and at least one selected from the group consisting of a methylene chain, a fluoromethylene chain, and a siloxane chain. Each of the first functional groups has bonded to the wiring lead.

Here, the first functional group of each of the functional organic molecules may be a compound, a chemical structure, or a derivative having at least one selected from the group consisting of a thiol compound, a sulfide compound, and a nitrogen-containing heterocyclic compound.

A yet another aspect of the present invention provides a resin-coated metal part including: the wiring member according to the present invention and having a resin material adhered to a surface region thereof. The surface region of the wiring lead covered by the organic coating is greater in area than the surface region of the wiring member where the resin material is adhered.

Here, the resin may be a thermosetting resin.

Here, the thermosetting resin may be a compound, a chemical structure, or a derivative having at least one selected from the group consisting of an epoxy resin, a phenol resin, an acryl resin, a melamine resin, a urea resin, an unsaturated polyester resin, an alkyd resin, a polyimide resin, a polyamide resin, and a polyether resin. Each second functional group may be a compound, a chemical structure, or a derivative having at least one selected from the group consisting of a hydroxyl, a carboxylic acid, an acid anhydride, a primary amine, a secondary amine, a tertiary amine, an amide, a thiol, a sulfide, an imide, a hydrazide, an imidazole, a diazabicyclo-alkene, an organic phosphine, and a boron trifluoride amine complex.

Here, the thermosetting resin may be a silicone resin or a silicone resin having at least either of an epoxy group and an alkoxysilyl group. Each second functional group may be a compound, a chemical structure, or a derivative having at least one selected from the group consisting of a vinyl group, an organohydrogensilane, a hydroxyl, an acid anhydride, a primary amine, and a secondary amine.

Here, each second functional group may be a compound, a chemical structure, or a derivative having at least one selected from the group consisting of platinum, palladium, ruthenium, and rhodium. Note that the silicone resin may also be a silicone resin-containing conductive paste (a die bonding agent).

Here, each second functional group may be a compound, a chemical structure, or a derivative having at least one selected from the group consisting of a fluorescent compound and a phosphorescent compound.

A yet another aspect of the present invention provides a resin-sealed semiconductor device including: the wiring member according to the present invention; and a semiconductor element electrically connected to the wiring lead. A portion of the wiring lead is externally exposed. The semiconductor element is sealed with a resin within the surface region of the wiring lead covered by the organic coating.

A yet another aspect of the present invention provides a wiring member including: a wiring lead composed of a metallic material; and an organic coating disposed to cover a surface region of the wiring lead. The organic coating is composed of a plurality of self-assembled functional organic molecules. A thermosetting resin material is adhered to a portion of the wiring member. Each of the functional organic molecules has a chemical structure having a main chain, a first functional group, and a second functional group. Each of the first functional group and the second functional group is provided at a different end of the main chain. The first functional group is in a form for bonding to the wiring lead by any one or more of a metal bond, a hydrogen bond, and a coordinate bond by a metal complex. The second functional group has a resin hardening property or a resin-hardening promoting property. Each of the first functional groups has bonded to the wiring lead. The second functional group is a compound, a chemical structure, or a derivative having at least one selected from the group consisting of a vinyl group, an organohydrogensilane, a hydroxyl, an acid anhydride, a primary amine, and a secondary amine. The thermosetting resin is a silicone resin or a silicone resin modified with at least either of an epoxy group and an alkoxysilyl group. The organic coating is formed to cover a surface region of the wiring lead that is greater in area than the surface region of the wiring lead where the resin is adhered.

### ADVANTAGEOUS EFFECTS OF INVENTION

In the present invention having the above structure, an organic coating formed by the self-assembly of functional organic molecules is provided on a surface of a wiring lead composed of a metallic material, thereby enabling various types of favorable chemical actions between the organic coating and the resin material that adheres thereto.

Specifically, by providing the first functional group that exhibits a metal bonding property at one end of a main chain of the functional organic molecule, the functional organic molecule self-assembles on the wiring lead surface with the second functional group facing away from the wiring lead surface, thereby forming the organic coating. Accordingly, giving the second functional group a resin hardening property, a resin-hardening promoting property, or the like, enables increasing the bonding force between the wiring lead surface and the organic coating that has adhered thereto, and speeding up the hardening of the resin material.

As a result, even if, for example, there is a gap between the dies during injection molding, the resin that fills the cavity can be effectively suppressed from leaking into the gap due to speedily hardening on the organic coating. As such, there is no need for an extra step of eliminating resin burrs after resin molding. The present invention can also be realized by only using the organic coating, and there is no need to modify existing injection molding apparatuses or add a separate apparatus. This enables the realization of a semiconductor device that has favorable electrical connectivity at low costs and with superior manufacturing efficiency.

Further, by employing the organic molecules described above, a semiconductor device having a sealing resin (resin mold) and a wiring lead that are firmly bonded to each other via an organic coating is realized. That is, the risk is minimized that gaps are formed between the facing surfaces of the sealing resin and the wiring lead. Therefore, even if water present in the ambient atmosphere somehow enters into the semiconductor device, it is prevented that water accumulates between the sealing resin (resin mold) and the wiring lead. Thus, the following problems conventionally caused by the accumulated water are appropriately avoided. That is, occurrence of cracks and detachment at the time of reflow of the semiconductor device is duly prevented, and shorting in the semiconductor chip via water infiltrated through a crack is duly prevented.

Also, by using a compound including a vinyl group, an organohydrogensilane, a hydroxyl, an acid anhydride, a primary amine, and a secondary amine etc. as the second functional group, the organic coating obtains a secure chemical bond with the silicone resin or with the silicone resin having at least either of an epoxy group and an alkoxysilyl group. Accordingly, forming an organic coating composed of such functional organic molecules on the wiring leads of an LED device enables suppressing the occurrence of problems such as cracks in and peeling of the silicon resin and the wiring lead, degradation in performance due to poor contact under high temperature, and insufficient bond strength, and also enables the realization of stable luminous efficiency in the LED device. In addition, since the main chains of the organic coating are precisely arranged, discoloring of Ag that would otherwise be caused by platinum group catalyst required for addition polymerization of the silicone resin and/or a corrosive gas is suppressed.

Furthermore, in the structure of the LED device, providing the surface of the wiring leads with an organic coating composed of functional organic molecules that include a platinum complex as the second functional group causes the silicone resin filled thereon to harden very quickly. Even if unnecessary gaps are formed between the reflector and the wiring leads, the present invention effectively prevents the silicone resin from flowing into the gaps. Note that the silicone resin may also be a silicone resin-containing conductive paste (a die bonding agent such as an Ag paste). Performing die bonding using the aforementioned silicone resin-containing conductive paste enables securely bonding the semiconductor chip to the die pad in an LED device or the like, and enables the stabilization of electrical and thermal conductivity due to a lower degree of degradation than when using a conventional epoxy resin-containing conductive paste.

Also, in the LED device, providing the wiring leads with an organic coating composed of functional organic molecules that include a fluorescent or phosphorescent compound as the second functional group enables improving the reflectivity with respect to ultraviolet light or short wavelength visible light. This holds even if the LED device is provided with an Ag plating coat, which has a low reflectivity with respect to short wavelength light. This achieves overall favorable luminous efficiency for the LED device.

In the case where an Ag plating coat is provided to cover a reflector formed to surround an LED chip of an LED device, the organic coating according to the present invention may be provided on a surface of the Ag plating coat. With the provision of the organic coating, the functional organic molecules that are densely arranged by the self-assembly prevent the Ag plating coat from making direct contact with unnecessary gas generated during the manufacturing process (outgas or the like derived from thermoplastic resin material of the reflector). As a result, alteration of Ag due to unnecessary gas is prevented, so that the reflectivity of the plating coat is maintained without being impaired, which ensures manufacturing of an LED device having a good luminous efficiency.

In addition, in the case where the reflector is made of a material such as a thermoplastic resin, the organic coating according to the present invention is provided, so that the wiring lead is prevented from making direct contact with outgas derived from the material. That is, the problems of non-bonding of wires that would otherwise be caused by the presence of the outgas are prevented, so that the wire bonding is performed with significantly improved reliability.

Also, in the film carrier tape, using functional organic molecules that include a first functional group having a metal bonding property for the wiring pattern layer and a second functional group having a bonding property for the solder resist layer enables maintaining a stable layer structure between the wiring pattern layer and the solder resist layer. This prevents the edges of the solder resist layer from peeling off of the wiring pattern layer in the Sn plating step during manufacturing, and enables the manufacture of a high quality film carrier tape by suppressing the occurrence of localized batteries. Furthermore, the effect of making the wiring pattern layer water-resistant can be achieved if the main chain, which occupies a large portion of the structure of the functional organic molecules in the organic coating formed on the wiring pattern layer, includes a hydrophobic hydrocarbon or fluorocarbon. This achieves the effect of suppressing migration and maintaining stable performance as a conducting part.

Note that in the present invention, the organic coating composed of a single molecule film (i.e., monomolecular film) is formed by the self-assembly of functional organic molecules and has a highly superior bonding property for the wiring leads. While having a single-molecule thickness, the present invention satisfies the demand for enhancing corrosion resistance, rust resistance, and anti-insulating properties of the area of the wiring leads where the organic coating is formed, and furthermore is very space efficient in the device. There is also no need to remove the organic coating after its provision. With respect to such points regarding functionality and structure, the present invention is entirely different from general surface preparation agents, surface activating agents, coating materials, and the like.

### BRIEF DESCRIPTION OF DRAWINGS

FIG. 1 show a structure of a semiconductor device pertaining to embodiment 1;

FIG. 2 is a schematic view showing a structure of a functional organic molecule pertaining to embodiment 1;

FIG. 3 shows a synthesis reaction process of the functional organic molecule having a second functional group with a resin hardening property, pertaining to embodiment 1;

FIG. 4 shows a synthesis reaction process of the functional organic molecule having a second functional group with a resin-hardening promoting property, pertaining to embodiment 1;

FIG. 5 show a film formation process for an organic coating pertaining to embodiment 1;

FIG. 6 show a resin adhering process pertaining to embodiment 1;

FIG. 7 shows a structure of an LED device pertaining to embodiment 2;

FIG. 8 show a structure of and manufacturing process for an LED device pertaining to embodiment 3;

FIG. 9 shows a synthesis reaction process of a functional organic molecule pertaining to embodiment 3;

FIG. 10 show a structure etc. of an LED device pertaining to embodiment 4;

FIG. 11 shows a synthesis reaction process of a functional organic molecule pertaining to embodiment 4;

FIG. 12 show a structure of an LED device pertaining to embodiment 5;

FIG. 13 shows a synthesis reaction process of a functional organic molecule pertaining to embodiment 5;

FIG. 14 show a structure of an LED device pertaining to embodiment 6;

FIG. 15 show a manufacturing process for a film carrier tape pertaining to embodiment 7;

FIG. 16 are structural views showing a periphery of a functional organic molecule pertaining to embodiment 7;

FIG. 17 shows a synthesis reaction process of the functional organic molecule pertaining to embodiment 7;

FIG. 18 show a manufacturing process for a film carrier tape pertaining to embodiment 8;

FIG. 19 are structural views showing a periphery of a functional organic molecule pertaining to embodiment 8;

FIG. 20 shows a synthesis reaction process of the functional organic molecule pertaining to embodiment 8;

FIG. 21 show a manufacturing process for a film carrier tape pertaining to embodiment 9;

FIG. 22 show steps during conventional injection molding of a semiconductor device;

FIG. 23 are cross-sectional views illustrating a problem associated with a conventional semiconductor device;

FIG. 24 show a schematic view of a localized battery formation process and a structure of a film carrier tape according to conventional technology; and

FIG. 25 show a structure of a film carrier tape having two Sn plating layers according to conventional technology.

### REFERENCE SINGS LIST

A1-A5 First functional group
B1-B5 Main chain
C1-C5, C2′ Second functional group
3 Wiring lead
3a, 3b Die pad
10 Semiconductor device (QFP)
11-15, 12a Functional organic molecule
21 Molded resin
22 Reflector
30 Wiring lead
31 LED device
40 Film carrier tap
42 LED chip
63 Ag plating coat
82a Leaked resin
110, 120, 120a, 130, 140 Organic coating
301, 302 Exposed region
301a Outer lead
302a Inner lead
401 Insulation film
402 wiring pattern layer
403x Edge
403 Solder resist layer
404 Sn plating layer
406 Corroded region
408 Sn deposition layer

### DESCRIPTION OF EMBODIMENTS

Embodiments of the present invention are described below with reference to the drawings.

Naturally, the present invention is not limited to the following embodiments and various modifications may be made without departing from the gist of the present invention.

### Embodiment 1

### 1. Semiconductor Device Structure

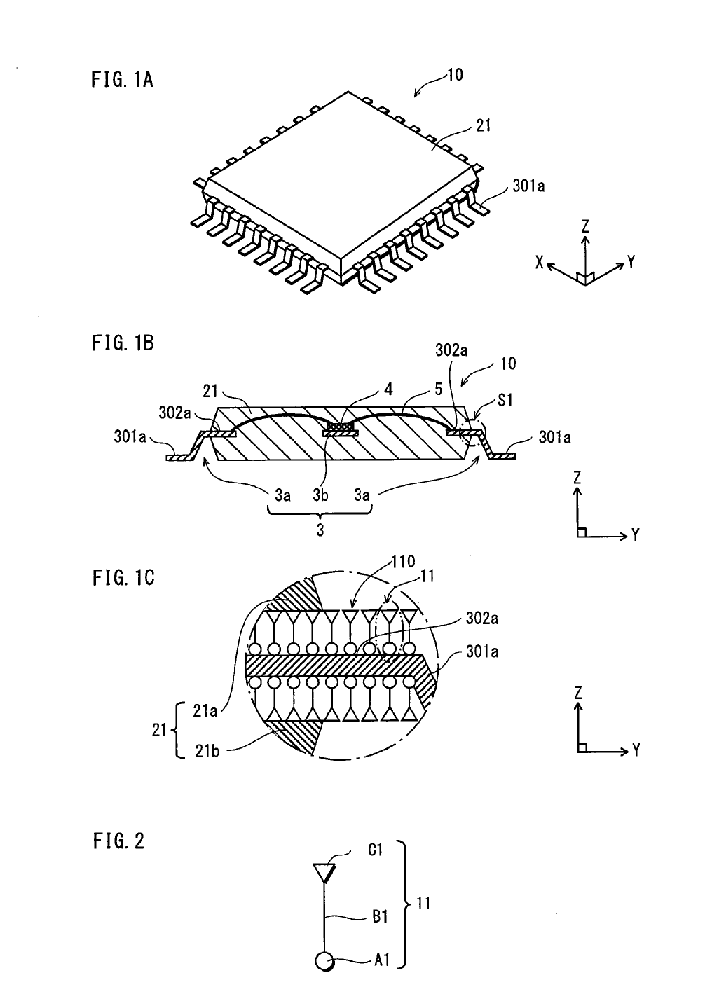

FIG. 1A is an external perspective view showing a structure of a semiconductor device (QFP 10, Quad Flat Package), which is an exemplary application of the present invention. FIG. 1B is a cross-sectional view taken along a y-z plane of the QFP 10. FIG. 1C is an enlarged view of portion S1 in FIG. 1B.

The QFP 10 is a surface-mounted semiconductor device used in an IC, LSI etc., and is composed of a semiconductor chip 4, a wiring lead 3, wires 5, a molded resin 21, and the like.

The wiring lead 3 is constituted from a metallic material that has superior electrical conductivity (e.g., copper alloy), and has a structure that also includes die pads 3a and 3b that have been punched out of a metal plate.

As shown in FIG. 1A, the QFP 10 has a structure that includes the molded resin 21 formed in a board shape and having a predetermined thickness and square main surface, and outer leads 301a that are a part of the die pads 3a and extend out from a circumference of the molded resin 21.

As shown in FIG. 1B, the molded resin 21 has an internal structure in which the semiconductor chip 4 has been mounted on the die pad 3 and electrically connected to the die pads 3a and 3b via the wires 5 and electrode pads which are not depicted. Although not depicted, the die pad 3b and the semiconductor chip 4 are joined by an electrically conductive paste such as silver paste. An inner lead 302a is an region of each of the die pads 3a that is sealed in the molded resin 21, and an outer lead 301a is an region of each of the die pads 3a that is exposed to the exterior. Each of the outer leads 301a has been bent into an S shape with respect to a cross-sectional structure thereof.

Here, a characteristic feature of the QFP 10 is that an organic coating 110 formed by self-assembling functional organic molecules has been provided on surfaces of the die pads 3a at a border region of the inner leads 302a and the outer leads 301a (portion S of FIG. 1B).

The following is a detailed description of the organic coating 110.

### 2. Structure of the Organic Coating 110

FIG. 2 shows a schematic structure of a functional organic molecule 11. The functional organic molecule shown in FIG. 2 includes a first functional group A1, a main chain B1, and a second functional group C1 that have been combined in the stated order.

The main chain B1 includes a component such as a glycol chain, a methylene chain, a fluoromethylene chain, a siloxane chain, or the like.

The first functional group A1 is a functional part that is constituted from one of or a combination of a compound, chemical structure, or derivative that exhibits a metal bonding property.

The second functional group C1 is a functional part that is constituted from one of or a combination of a compound, chemical structure, or derivative that exhibits a hardening effect or hardening-promoting effect on thermosetting resin.

As shown in FIG. 1C, given that the first functional group A1 orients itself so as to bond to the surface of the die pad 3a composed of a metallic material, each of the functional organic molecules 11 is oriented such that the second functional group C1 at the other end of the main chain B1 faces away from the surface of the die pad 3a. Accordingly, there is formed a single molecule film (organic coating 110) with molecular orientation-related chemical properties (e.g., mutual affinity), that is to say, there is formed a self-assembling structure. The film thickness of the organic coating 110 depends on the length of the functional organic molecules 11, but is adjusted here to the order of several nm (FIG. 1C).

Accordingly, the organic coating 110 can precisely protect the surface of the die pad 3a at the single-molecule level, and as a result, can function to prevent corrosion by the adhesion of water and oxygen gas, and favorably prevent the generation of substitution reaction in which noble metal salts are formed.

Note that it is necessary to perform electrical connection with the semiconductor chip 4 by wire bonding, die bonding, or the like to the outer leads 301a, and there are cases in which a coating such as a metal plating coat is formed on connection regions of at least the die pads and the wiring lead 3 in order to maintain favorable electrical conductivity. Given that a metal plating step is required in such cases, it is preferable to provide the organic coating 110 on portions of the die pad 3a surface that have not been plated, thereby enabling suppression of the problem of the metallic component of the die pad 3a eluting into the plating fluid due to the ionization tendency of the metallic component.

The general formula of the functional organic molecules 11 is expressed as A1-(B1)ₙ-C1. In the formula, it is favorable for n to be approximately 4 to 40. If n is too small, the main chain B1 is too short, there is a weakening of the inter-molecule hydrophobic affinity action, which arises from the hydrophobic property of the main chain B1, between the functional organic molecules 11 when the first functional group A1 adheres to the die pads 3a, and the outward-facing orientation of the second functional group C1 is readily lost. Also, if n is too large, the main chain B1 is too long, and the ability to solder, wiring bond, die bond, etc. with the die pad 3a is readily impaired.

Note that the main chain B1 may have a structure in which a lateral chain is arbitrarily joined thereto. Further, by introducing a hydrophilic glycol chain as part of the main chain, strong orientation of the organic molecules of the organic coating 110 is obtained by the action of both hydrophobic affinity and hydrophilic affinity.

The following is a detailed description of possible chemical structures of the functional organic molecules 11 of embodiment 1.

### First Functional Group A1

As mentioned above, it is required that the first functional group A1 have affinity with metallic materials and a metal bonding property (including coordinate bonding). The first functional group A1 may be any one of or a combination of a compound, chemical structure, or derivative, as long as the above properties are ensured.

For example, hydrogen bonding or coordinate bonding with metal atoms is favorably ensured when using thiol, a thiol compound, a sulfide compound (e.g., a disulfide compound), a nitrogen-containing heterocyclic compound (e.g., an azole compound or azine compound), or one of or a combination of a compound, chemical structure, or derivative that includes any of the above compounds.

If the first functional group A1 includes a thiol group (R—SH, where R is an arbitrary functional group such as alkane or alkene), the functional organic molecules 11 adhere to the die pad 3a by coordinating with a metal atom that can become a single-valent or greater cation (e.g., a gold (Au) or silver (Ag) atom), and forming a covalent bond such as Au—S—R or Ag—S—R. Similarly, if the first functional group A1 is a disulfide group (RH—S—S—R₂) covalent bonds such as Au (—S—R₁) (—S—R₂) or Ag (—S—R₁) (—S—R₂) are formed, thereby obtaining a strong bond structure.

If the first functional group A1 includes an azole compound or an azine compound, non-covalent electron pairs of nitrogen atoms in the components of these compounds can form coordinate bonds with metals that can be double valent or greater cations. This is favorable since, for example, imidazole compounds, benzotriazole compounds, trazine compounds and the like readily form mainly coordinate bonds with metals such as Cu.

Note that covalent bonds, coordinate bonds, hydrogen bonds etc. are formed at the same time depending on the type of the compound. Even stronger bond structures can therefore be achieved since two or more types of bonds are formed.

### Regarding Main Chain B1

The main chain B1 can be a general methylene series organic molecule or various types thereof (a compound, chemical structure, or derivative including one or more of a methylene chain, a fluoromethylene chain, a siloxane chain and a glycol chain) or the like. A methylene chain is favorable since molecules therein can assemble with each other to supramolecularly form a precise carbon chain of a hydrocarbon chain. Also, it has become clear upon examination by the inventors that the organic coating can be formed relatively speedily if a methylene chain is used.

If a fluoromethylene chain is used as the main chain B1, the infiltration of water between the wiring lead 3 and the organic coating is suppressed to a great degree since the organic coating is more hydrophobic than when using the methylene chain. This is favorable since preferable bonding between the organic coating and the wiring lead is maintained, and detachment of the organic coating due to thermal history does not readily occur.

Thermal resistance and weatherability properties can be achieved if a siloxane chain is used in the main chain B1. This enables the effect of preventing deformation and damage to the organic coating even if exposed to a relatively high temperature environment in, for example, an implementation step for semiconductor elements etc.

If a glycol chain is used as the main chain B1 of organic molecules, the organic coating is formed by the hydrophilic interaction. Such organic molecules are advantageous as they easily dissolve in polar solvent such as water. In view of this, it is preferable to use the main chain B1 composed of a glycol chain alone or of a glycol chain and at least one selected from a methylene chain, a fluoromethylene chain, and a siloxane chain.

### Regarding Second Functional Group C1

It is required that the second functional group C1 have a resin hardening property or a resin-hardening promoting property for thermosetting resin. The second functional group C1 may be any one of or a combination of a compound, chemical structure, or derivative, as long as the above properties are ensured.

For example, the second functional group C1 may be one of or a combination of a compound, chemical structure, or derivative that includes one or more of a compound containing a hydroxyl group, a compound containing a carboxylic acid, a compound containing an acid anhydride, a compound containing a primary amine, a compound containing a secondary amine, a compound containing a tertiary amine, a compound containing a quaternary ammonium salt, a compound containing an amide group, a compound containing an imide group, a compound containing a hydrazide group, a compound containing an imine group, a compound containing an amadine group, a compound containing an imidazole, a compound containing a triazole, a compound containing a tetrazole, a compound containing a thiol group, a compound containing a sulfide group, a compound containing a disulfide group, a compound containing a diazabicylco-octane, an organic phosphine compound, or a compound containing a boron trifluoride amine complex. If any of these compounds, derivatives thereof, etc. are used, a hardening reaction instantly occurs when there is contact with the thermosetting resin, thereby bonding the second functional group C1 and the resin together.

If phthalic anhydride, which is an acid anhydride, is used, the second functional group C1 acts as an epoxy resin hardening agent, and forms a bond by ring-opening polymerization with the epoxy groups in the epoxy resin.

If 1,8-diazabicyclo(5.4.0) undecene-7 (DBU), which is a compound including diazabicyclo-undecene, is used, the second functional group C1 acts a hardening promoting agent for the epoxy groups in the epoxy resin and hydroxyl groups, acid anhydrides etc., thereby accelerating the polymerization reaction of the epoxy groups and the hydroxyl groups, acid anhydrides etc.

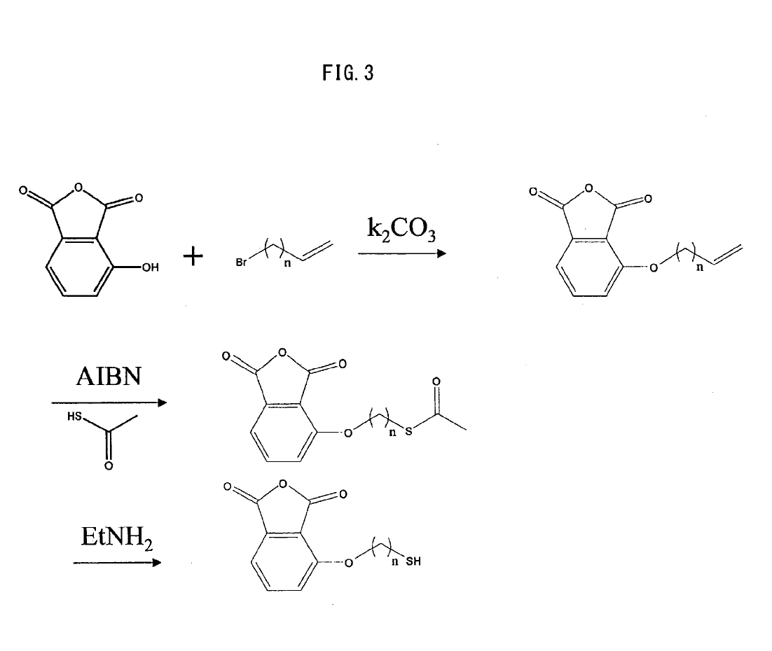

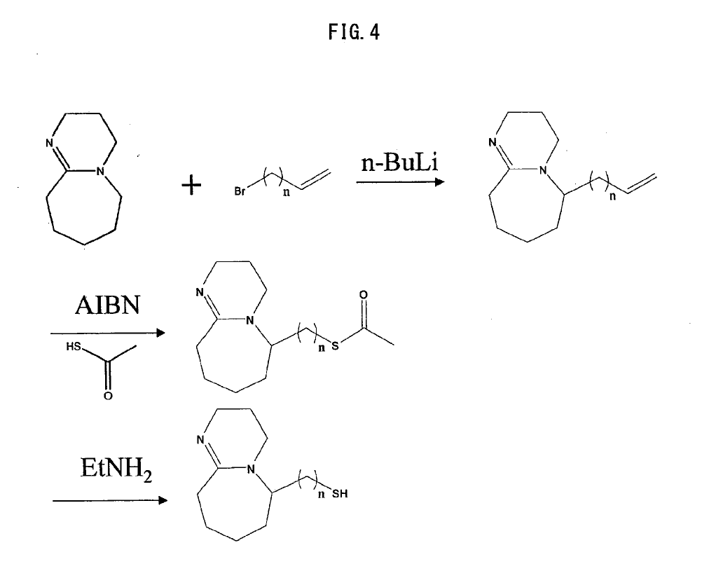

FIG. 3 shows a synthesis reaction process of the functional organic molecule 11 in which the first functional group is a thiol group, the main chain is a methylene chain, and the second functional group is phthalic anhydride.

As shown in FIG. 3, an ether bond is formed between vinylalkane having bromine at one end and 3-hydroxy phthalic anhydride in the presence of potassium carbonate by a hydrogen bromide elimination reaction, and an ethane removal condensation reaction is caused between the resulting compound and acetyl thiol in the presence of AIBN (2,2-azobis(2-methylpropionitrile)). One end of the resulting compound can be converted to thiol by a hydrogen replacement reaction by ethylamine.

FIG. 4 shows a synthesis reaction process of the functional organic molecule 11 in which the first functional group is a thiol group, the main chain is a methylene chain, and the second functional group is DBU.

First, the DBU and the vinylalkane having bromine at one end are bonded in the presence of normal butyllithium by a hydrogen bromide elimination reaction. Thereafter, an ethane removal condensation reaction is caused between the resulting compound and acetyl thiol in the presence of AIBN. One end of the resulting compound can be converted to thiol by a hydrogen replacement reaction by ethylamine.

### 3. Manufacturing Method for the Semiconductor Device

The following is a description of a manufacturing method for the QFP 10 of embodiment 1.

The QFP 10 is manufactured by an organic coating formation step of depositing the organic coating 110 on predetermined surfaces of the die pad 3a, and thereafter a resin adhering step of resin-sealing the die pad 3a, the semiconductor chip 4, and the like.

### 3.1 Organic Coating Formation Step

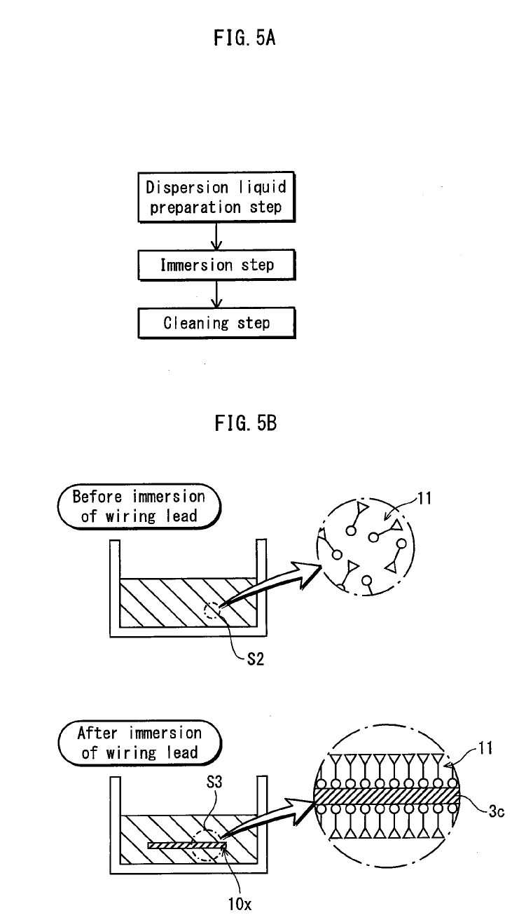

The organic coating formation step includes a dispersion fluid preparation substep, a film formation substep, and a cleaning substep in the stated order (FIG. 5A).

### Dispersion Fluid Preparation Substep

The dispersion fluid is prepared by dispersing the functional organic molecules 11 in a predetermined solvent. The solvent may be an organic solvent and/or water. When water is used as the solvent, it is preferable to add an anion series, cation series, or nonion series surface-activating agent as necessary in order to obtain dispersal of the functional organic molecules 11. Furthermore, a boric acid series, phosphoric acid series, or other pH buffering agent may be added in order to stabilize the functional organic molecules 11.

### Film Formation Substep

Next, the predetermined surfaces of the die pad 3a are immersed in the prepared dispersion fluid.

In the dispersion fluid, each of the functional organic molecules 11 is at an energy level having relatively high Gibbs free energy, and is moving randomly in reactive directions due to interaction between molecules (so-called Brownian motion).

Consequently, when the die pad 3a composed of a metallic material is immersed in the dispersion fluid, the functional organic molecules form metallic bonds with the die pad 3a on the micro level by the first functional group, and attempts to transition to a more stable state.

On the macro level, this transition to a stable state involves each of the functional organic molecules 11 stabilizing itself by bonding its first functional group A1 to the surface of the die pad 3a, while aligning its main chain B1 and second functional group C1, thereby self-assembling to form a single molecule film (FIG. 5B).

The die pad 3a is lifted out of the dispersion fluid after the self-assembling film has been formed according to the above principle. This obtains a member constituted from the die pad 3a on which the organic coating 110 has been formed (hereinafter, called a “wiring member 10x”).

Note that although FIG. 5B describes an exemplary case in which the organic coating 110 is formed on all surfaces of the die pad 3a, a pattern mask having apertures of a predetermined shape of course may be placed on the surface of the die pad 3a, and the organic coating 110 may be formed on only surface portions of the die pad 3a that correspond to the apertures.

Note that although an immersion method using a dispersion fluid has been described above, the method of forming the organic coating 110 is not limited to this. For example, another method such as spraying may be used to form a similar organic coating 110.

### Cleaning Substep

Cleaning processing is performed by using an organic solvent and/or water as a cleaning medium to remove excess functional organic molecules 11 from the wiring member 10x lifted out of the dispersion fluid. Functional organic molecules 11 that have not formed a direct metallic bond with the first functional group A1 should be removed since they do not contribute to the effect of the present invention. The cleaning substep enables the simple removal of functional organic molecules 11 that have not formed a metallic bond with the die pad 3a.

This completes the organic coating formation step.

### 3.2 Resin Adhering Step

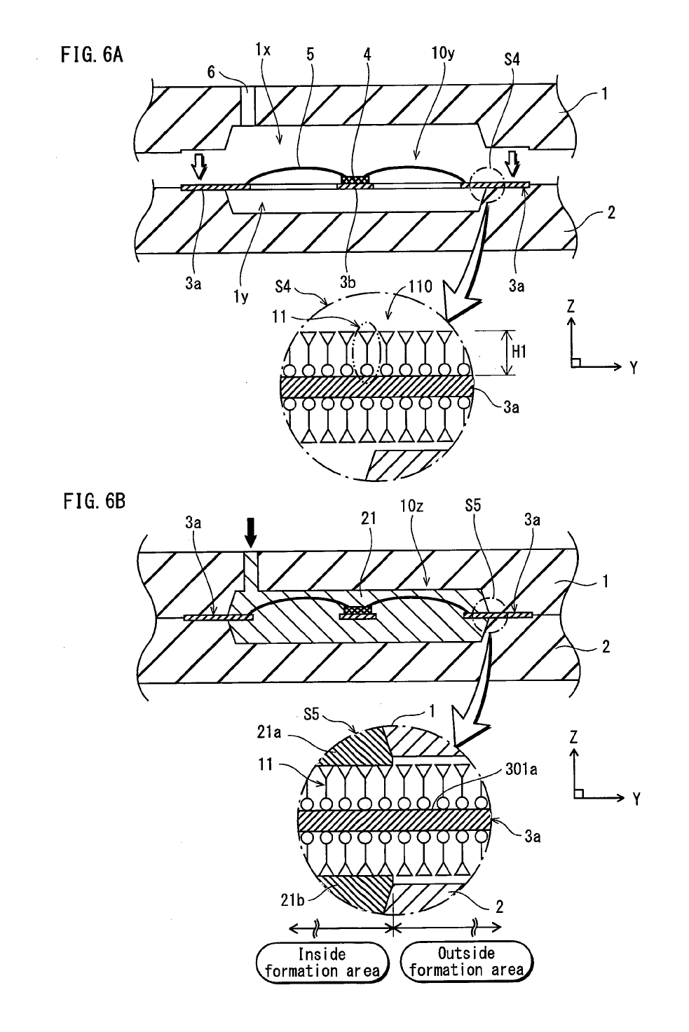

The resin adhering step includes a wiring member mounting substep and a resin filling substep in the stated order. The following describes each of these steps with reference to the schematic views of FIGS. 6A and 6B.

### Wiring Member Mounting Substep

First, the semiconductor chip 4 is mounted to the die pad 3b. The semiconductor chip 4 is connected to the wiring member 10x created in the organic coating formation step via the wiring lead 5 etc. A resulting chip-attached wiring member 10y is placed on the fixed die 2 (FIG. 6A).

Next, the movable die 1 is moved in the direction of the arrows to close the dies 1 and 2. At this time, the precise organic coating 110 has been formed to a single-molecule level thickness H1 on the surface of the wiring lead 3 of the chip-attached wiring member 10y, with the second functional groups C1 of the functional organic molecules 11 facing away from the surface of the wiring lead 3 (enlarged view of portion S4 of FIG. 6A). The region where the organic coating 110 has been formed includes regions that do not directly face cavities 1x and 1y (interior spaces) secured between the dies 1 and 2. In other words, the region of the organic coating 110 is a larger region than where the resin sealing is to be performed later.

### Resin Filling Substep

The dies 1 and 2, which are in the closed state, are set to a predetermined heated condition. A fluid-state thermosetting resin material is injected into the cavities 1x and 1t a predetermined pressure via the gate 6. The resin material is filled mainly in the region including the semiconductor chip 4 of the chip-attached wiring member 10y until the cavities 1x and 1y are completely filled, and then hardens by receiving heat from the dies 1 and 2 (FIG. 6B). Formation of the sealing resin is complete once the resin material has completely hardened after a predetermined time, thereby obtaining a QFP 10z. The QFP 10 is then completed by bending the outer leads 301a.

In this step, portions of the filled resin material that come into contact with the organic coating 110 are affected by the second functional group C1 (resin hardening effect or resin-hardening promoting effect), and harden relatively quickly (“IN FORMATION REGION” of FIG. 6B). Even if there are unnecessary gaps between facing surfaces of the dies 1 and 2, the above effect causes the resin material to almost completely harden before leaking into the gaps between the dies at the periphery of the cavities 1x and 1y (“OUTSIDE OF FORMATION REGION” of FIG. 6B). This enables effectively suppressing the formation of resin burrs in gaps between the dies 1 and 2 (enlarged view of portion S5 in FIG. 6B). Accordingly, it is possible to greatly reduce the occurrence of resin burrs on the outer leads 301a of the semiconductor device after formation of the sealing resin. This eliminates the need for a separate processing step for removing resin burrs and enables a speedy transition to other steps such as for connecting the semiconductor device to another substrate, thereby realizing superior manufacturing efficiency.

Compared with conventional technology, the use of the organic coating 110 in the QFP 10 obtained by the aforementioned steps ensures stronger adhesion between the die pad 3a and the molded resin. Consequently, when the QFP 10 is connected to another substrate, there is no resin detachment from the wiring lead due to heat damage, nor are there failures such as cracks. Moreover, given that the main chain of the functional organic molecules exhibit a hydrophobic property, precisely providing such molecules on the surface of the wiring member enables suppressing unnecessary adsorption of water to the wiring lead. This also suppresses ionization of the surface metal due to the application of a voltage, thereby achieving the effect of suppressing migration.

Also, since the organic coating 110 is a single molecule film, the provision thereof causes almost no increase in the thickness of the semiconductor apparatus, and there is also no problem of the volume of the organic coating causing a practical shortage of resin material to be filled into the cavities. As such, the excellent effects of the present invention can be obtained while using the same manufacturing facilities as in conventional technology.

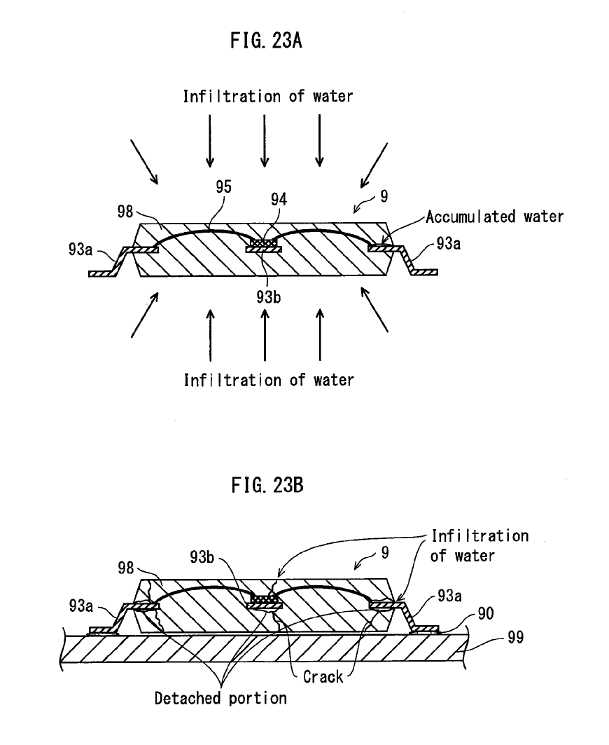

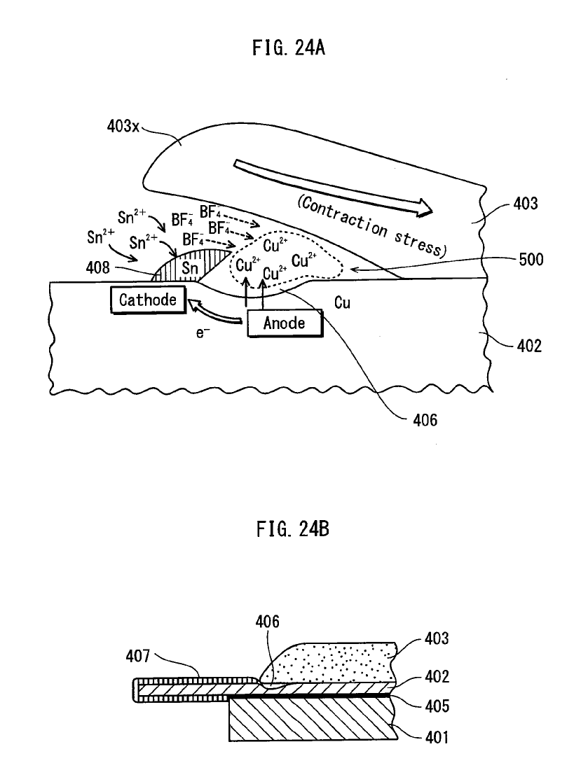

In addition, as another effect, the QFP 10 is protected from problems, such as the occurrence of cracks and detachment between the wiring lead and the resin that would otherwise be caused by infiltration of water into the sealing resin (molded resin). Generally speaking of QFPs, the sealing resin (molded resin) tends to be infiltrated with water from the ambient atmosphere (FIG. 23A). In the case of a conventional QFP, the adhesion between the resin and the wiring lead may be insufficient, so that there may be gap(s) between the facing surfaces of the resin and the wiring lead. Thus, water infiltrated into the resin tends to be accumulated in the gaps by capillary action. When heat (about 260° C.) is applied for the reflow process to mount the QFP 10 in this state on a substrate, the accumulated water evaporates at once and undergoes rapid volume expansion. At this time, a considerable amount of water in the resin cannot withstand the rapid volume expansion. As a result, one or more portions of the resin each corresponding to a gap may be pealed from the wiring lead to form detached portions or one or more cracks each running from a gap to reach the outer surface of the sealing resin (molded resin) may be generated (FIG. 23B). Such detached portions and/or cracks tend to invite more impurities such as water to be entered into the QFP from the outside. Such impurities may cause rupturing or shorting of a circuit of the semiconductor chip 94 sealed with resin.

Even if a visible breaking as described above does not occur at the time of reflow, water accumulated in the gaps may eventually cause shorting or corrosion in the semiconductor chip 94 and thus result in operation failure.

On the other hand, the QFP 10 described above is provided with the organic coating formed on the surface of the wiring lead, so that the adhesion with the sealing resin (molded resin) is significantly improved as compared with the conventional QFP. The good adhesion is maintained even after manufacturing of the QFP 10 is completed, so that the risk is minimized that gaps are formed between the facing surfaces of the sealing resin and the wiring lead. Therefore, even if water present in the ambient atmosphere is infiltrated into the sealing resin (molded resin) due to the progress made after the manufacturing, the resin is without any gap that may hold a considerable amount of water. As described above, the QFP 10 is mounted onto the substrate without forming detached portions and cracks, so that high sealing reliability is maintained. In addition, the problems resulting from water are continuously prevented even after the mounting of the QFP 10.

### Embodiment 2

The organic coating 110 composed of the functional organic molecules 11 pertaining to the present invention has various effects when applied to a semiconductor device as mentioned above, but this is nothing more than one example. The existence of a semiconductor chip is not required. For example, the organic coating 110 can be applied to an LED device that includes a light emitting diode (LED) element instead of a semiconductor chip.

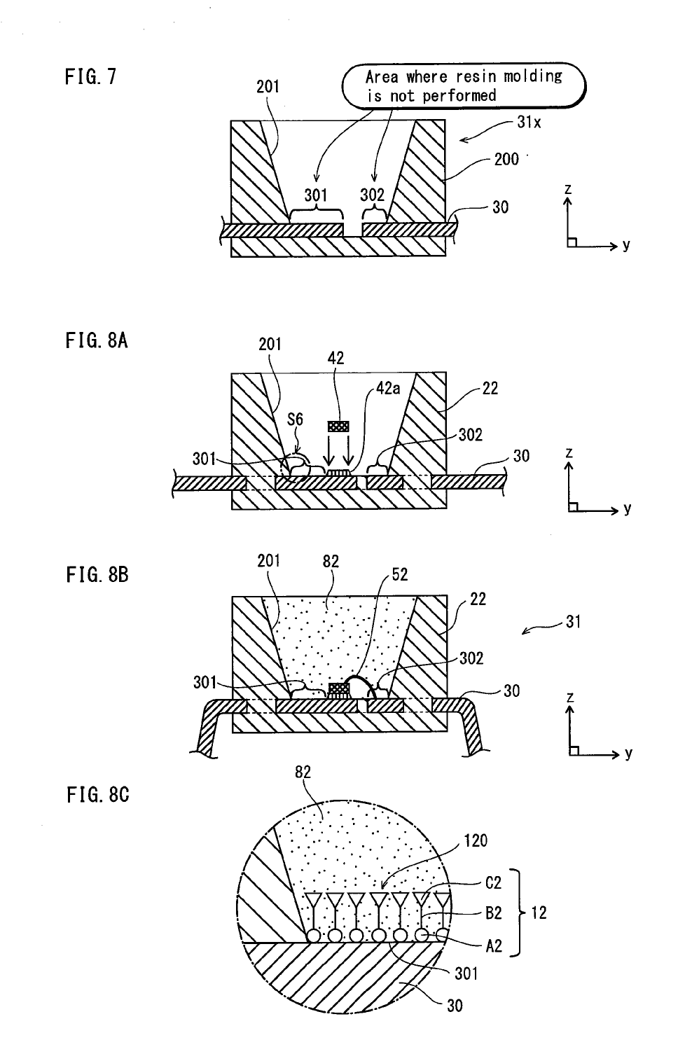

FIG. 7 is a schematic cross-sectional view showing a structure of a wiring lead 30 and a reflector 22 of an LED device unit 31x of embodiment 2 of the present invention.

In a cross-sectional structure of the LED device unit 31x, the wiring lead 30 has been provided on a bottom portion of the bowl-shaped reflector 22. The reflector 22 may be formed by a resin mold using a thermosetting resin material (e.g., epoxy resin, silicone resin and the like). Alternatively, the reflector 22 may be formed by using a ceramics material.

Similarly to embodiment 1, there is the possibility of resin burrs forming in the LED device unit 31x as well. Specifically, regions 301 and 302 of the wiring lead 30 that are exposed at the bottom of the reflector 22 must retain conductivity since an LED chip 42 is mounted thereupon later (see FIG. 8B), and due to the same principle as in embodiment 1, resin burrs can form on the exposed regions 301 and 302 during resin molding, from the bottom edges of the reflector 22 through gaps between the dies. Another processing step for removing the resin burrs is therefore necessary, and the LED cannot be mounted with favorable manufacturing efficiency.

Here, forming the organic coating 110 composed of the functional organic molecules 11 of the present invention on at least the exposed regions 301 and 302 of the wiring lead 30 before the resin adhering step enables speedily hardening the thermosetting resin material during resin molding. This prevents the resin material from leaking from the bottom edges of the reflector 22 and resolves the aforementioned problems pertaining to the occurrence of resin burrs.

### Supplementary Remarks about Embodiments 1 and 2

The hardening promoting effect for thermosetting resin that is achieved by providing the organic coating 110 in embodiments 1 and 2 can also be used to securely form a fine resin pattern.

For example, there is a case in which precise resin molding is required in the technological field of performing localized resin molding on a portion of a wiring plate surface by an inkjet method. In this case, first forming the organic coating enables faster resin molding than can be performed in a case of performing resin molding directly on the wiring lead 30. Resin dripping and loss of resin shape after application do not readily occur since the hardening time is short, which has the benefit of enabling the use of resin molding for precise patterns as planned.

Also, the organic coating of embodiments 1 and 2 is not limited to being formed directly on the die pad and the wiring lead. For example, a plating coat may be formed on the surfaces of the die pad and the wiring lead, and the organic coating may be formed thereupon. However, in this case the functional groups must be selected such that the second functional group C1 has the predetermined bonding properties.

### Embodiment 3

The following is a description of embodiment 3 of the present invention focusing on differences from embodiment 2.

### LED Device Structure

FIGS. 8A to 8C are cross-sectional views showing a structure of and manufacturing steps for an LED device 31 pertaining to embodiment 3 of the present invention.

The LED device 31 basically includes the device unit 31x of embodiment 2, and as shown in FIG. 8B, further includes an LED chip 42 that has been bonded, via a paste 42a, on the wiring lead 30 surrounded by the reflector 22. The LED chip 42 is connected to the wiring lead 30 via a wire 52.

A transparent sealing resin 82 is filled into the reflector 22 on a reflector surface 201 and the exposed regions 301 and 302 so as to seal the LED chip 42 and the like.

Silicone resin, which is one example of a thermosetting resin, is used as the sealing resin 82.

In embodiment 3, an organic coating 120, which is composed of a single molecule film formed by the self-assembly of functional organic molecules 12, has been formed on the surface of the exposed regions 301 and 302 of the wiring lead 30. The functional organic molecules 12 are expressed by the general formula A-(B)n-C, and have a characteristic feature in which a first functional group A2 having a metal bonding property is provided at one end of a main chain B2, and a second functional group C2 having a resin bonding property for silicone resin is provided at the other end of the main chain B2 (FIG. 8C).

In embodiment 3 having the above structure, peeling of the silicone resin from the wiring lead 30 is effectively prevented more than in conventional structures due to the presence of the organic coating 120 composed of the functional organic molecules 12 having the first and second functional groups A2 and C2.

Specifically, although having superior anti-discoloration properties and transparency over epoxy resin, silicone resin readily deforms under high temperatures due to having a high thermal expansion coefficient, and there is the fear that such deformation will cause the silicone resin to be peeled and detached from the wiring lead 30. In contrast, in embodiment 3 the use of the organic coating 120 composed of the functional organic molecules 12 causes a significant improvement in adhesion between the wiring lead 30 and the silicone resin, and suppresses the occurrences of peeling and detachment of the silicone resin from the wiring lead 30, even if, for example, the silicone resin is somewhat deformed by heat etc. This achieves stable functioning of the LED device 31 even in high temperature environments and during long periods of operation.

In addition, embodiment 3 achieves the effect of effectively preventing the problem of “non-bonding of wires” regarding the wire 52 for bonding the LED chip 42 to the wiring lead 30. That is, the reliability of the wire bonding is further improved.

More specifically, the resin material for forming the reflector 22 may be a thermoplastic resin, such as PPA (polyphthalamide resin) or LCP (liquid crystal polymer), instead of the thermosetting resin described above. Such a resin material contains a thermoplastic resin as a main component and also contains various additives mixed therein. Examples of the additives include thermostabilizer, light stabilizer, filler, mold lubricant, and white pigment. At the time of injection molding of the resin material fused by heat, volatile components present in the resin material containing the additives are released as outgas into the atmosphere. The outgas components derived from the mold lubricant and the base resin involve the risk of forming a thin film (impurity film) when adhered to the surface of the wiring lead. The presence of such an impurity film on the surface of the wiring lead will inhibit proper bonding between the wire tip and the wiring lead at the time of wire bonding. Even if the bonding is made, the bonding strength may be insufficient. In such a case, a slight vibration made thereafter may cause the wire to be detached and brought into the state of non-bonding. Note that the presence of an impurity film may be checked by SEM, for example.

In view of the above risk, the present invention provides the wiring lead 30 with a predetermined organic coating formed on a region of the surface of the wiring lead 30. By virtue of the organic coating, it is prevented that an impurity film is formed on the region. Here, it is noted that the outgas components derived from the mold lubricant and base resin are hydrophobic (lipophilic). Consequently, if the organic coating 120 is formed with the functional organic molecules 12, the second functional groups C2 exhibit hydrophilicity. Thus, the hydrophobic outgas components moving toward the organic coating 120 are repelled toward outside by the second functional groups C2. By virtue of this, the formation of an impurity film on the wiring lead 30 is efficiently prevented.

On the other hand, the following is noted regarding the wire 52 to be bonded to the wiring lead 30 via the organic coating 120. The width of the organic coating 120 is equal to the length of a single molecule of the functional organic molecules 12, whereas the diameter of the wire 52 is about 20 to 30 μm, which is relatively very thick (about 2000 to 3000 times the thickness of the organic coating). Therefore, at the time of bonding, a slight amount of the functional organic molecules 12 present in the bonding region is easily diffused into the wire that is fused due to the bonding load by ultrasonic energy and melts into the bonding metal present in the wire. As a result, the wire 52 is appropriately bonded to the wiring lead 30. In short, according to the present invention, wire bonding is performed to achieve higher bonding reliability by avoiding undesirable possibilities caused by outgas.

In order for the appropriate bonding, it is sufficient that the organic coating covers at least the specific surface region of the wiring lead 30 to which the wire is to be bonded. The organic coating covering an intended region is formed by appropriately masking the wiring lead 30 using a known method, before immersion into the dispersion fluid shown in FIG. 5.

Further, in the case where an Ag plating coat is formed on the surface of the wiring lead 30, an organic coating may be additionally provided on the plating coat. The organic coating serves to protect the Ag plating coat from a reactive gas and/or catalyst that may present in the ambient atmosphere, so that original reflectivity of the Ag plating coat is maintained and an LED device with excellent luminous efficiency is realized.

### Structure of the Functional Organic Molecules 12

The same first functional group A1 and main chain B1 of embodiment 1 can be used as the first functional group A2 and main chain B2 respectively in the functional organic molecules 12 of embodiment 3.

The second functional group C2 is a functional group, compound, or structure that has a hardening property for a thermosetting resin, and in particular for silicone resin. Specifically, the second functional group C2 can be any of a compound, chemical structure, or derivative that includes a vinyl group and/or an organohydrogensilane.

Further, in the case where the silicone resin has at least either of an epoxy group and an alkoxysilyl group, the second functional group C2 is a functional group, a chemical compound or a structure having a bonding property for a corresponding one of an epoxy group and an alkoxysilyl group. More specifically, as the second functional group C2, a functional group, compound or a chemical structure having at least one of a hydroxyl, an acid anhydride, a primary amine and a secondary amine is used. Such a functional group, compound or a chemical structure having a bonding property for a corresponding one of an epoxy group and an alkoxysilyl group is hydrophilic, so that adhesion of the hydrophobic outgas components described above is effectively prevented.

In order to improve the bonding to the second functional group C2, the resin component of the sealing resin 82 may additionally contain a hydrophilic additive having an epoxy group or an alkoxysilyl group as an agent improving the adhesion. With the addition of such an additive, the wiring lead 30 is firmly bonded to the sealing resin 82. In addition, the sealing resin 82 may be a transparent resin material having a silicone resin modified with an epoxy group or an alkoxysilyl group, which is hydrophilic. In addition, before sealing with the sealing resin, a silane coupling agent containing an alkoxysilyl group may be applied to the second functional group C2, so that the network of bonding to the sealing resin is further strengthened.

The above described functional group, compound or structure having at least either of an epoxy group and an alkoxysilyl group is more stable as compared to a vinyl group or organohydrogensilane and thus effective to improve the stability and longevity of the organic coating.

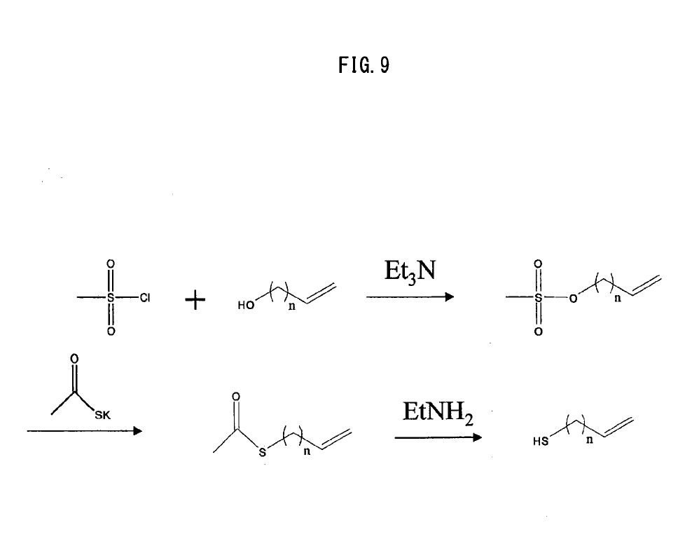

FIG. 9 shows an exemplary synthesis reaction process of a functional organic molecule 12 in which the first functional group A2 is a thiol group, the main chain B2 is a methylene chain, and the second functional group C2 is a vinyl group.

First, an ether bond is formed between methane sulfonyl chloride and vinylalkane having a hydroxyl group at one end in the presence of triethylamine, by hydrochloride elimination. In the resulting compound, the methane sulfonyl chloride part is replaced with acetylsulfide by thioacetate potassium. Thereafter, the acetylsulfide part is replaced with thiol by ethylamine. This obtains the functional organic molecules 12.

### Manufacturing Method for the LED Device

The manufacturing method for the LED device can be implemented by successively performing the following steps. Note that with the exception of the organic coating formation step, a heretofore known manufacturing method for an LED device may be employed.

### Organic Coating Formation Step

The organic coating 120 composed of the functional organic molecules 12 is formed as a self-assembled single molecule film on the surface of the wiring lead 30 in the same way as the organic coating formation step of embodiment 1, thereby obtaining the wiring lead 30 having an organic coating formed thereupon.

### Resin Adhering Step

A thermoplastic resin material such as polyphthalamide resin is injected onto the wiring lead 30, which has the organic coating 120 formed thereupon, in the same way as the injecting molding procedure shown in FIGS. 6A and 6B. Thereafter, cooling to a predetermined temperature range is performed to harden the resin. This forms the reflector 22 and obtains the LED device unit 31x.

Thereafter, the LED chip 42 is mounted on the wiring lead 30 via the paste 42a. The wiring lead 30 and LED chip 42 are connected via the wire 52.

Thereafter, the silicone resin material, which is in a fluid state, is filled into the reflector 22. The LED device 31 is then obtained by causing the resin to harden.

### Embodiment 4

The following is a description of embodiment 4 focusing on differences from embodiment 3.

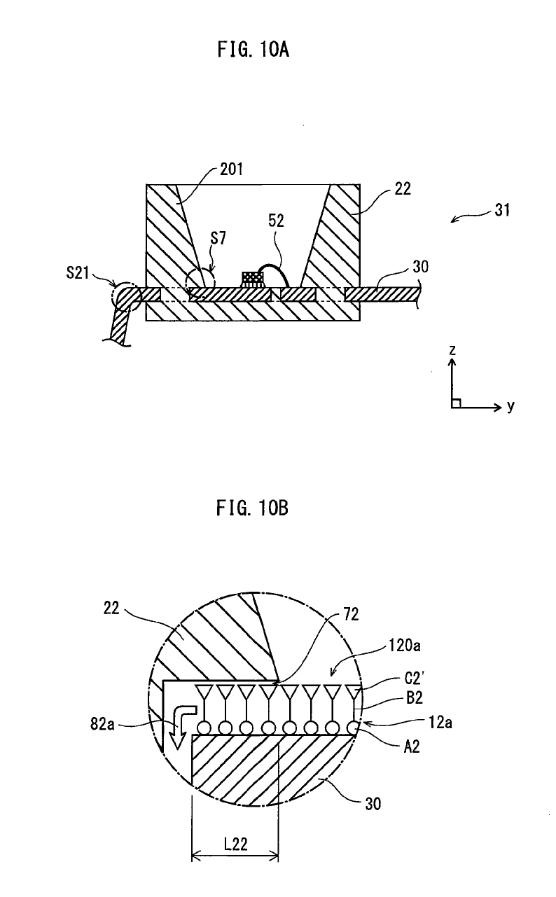

In embodiment 3, a functional group having a specialized chemical bonding property for silicone resin is selected as the second functional group C2 of the functional organic molecules 12 constituting the organic coating 120. However, embodiment 4 has a characteristic feature in that a functional group having a flash hardening property is selected as a second functional group C2′ of functional organic molecules 12a (enlarged view of portion S7 in FIG. 10B).

Specifically, the second functional group C2′ may be a compound, chemical structure or derivative that includes one or more of a platinum complex, a palladium complex, a ruthenium complex, and a rhodium complex.

A manufacturing method of the LED device of embodiment 4 is the same as the manufacturing method of embodiment 3.

In the LED device 31 having the above structure, the reflector 22 is formed by injection molding using a thermoplastic resin such as polyphthalamide resin.

At this time, the thermoplastic resin is cooled and hardened, and there are cases in which the resin experiences volume shrinkage. In such cases, there is the possibility of a gap 72 forming between the wiring lead 30 and the reflector 22 (FIG. 10B).

The gap 72 invites excessive leaked resin 82a during filling of the silicone resin, which is a waste of material. The leaked resin 82a also leads to the degradation of the electrical connectivity of the outer lead portion of the wiring lead 30, thereby requiring a separate removal step and bringing about a reduction in manufacturing efficiency. Furthermore, the leaked resin 82a is undesirable in that its existence under a heat sink (not depicted) attached to the back surface of the LED device 31 causes impairment of the radiation performance of the heat sink.

In contrast, in embodiment 4, a functional group having a flash hardening property is provided as the second functional group C2′ of the functional organic molecules 12a, thereby causing the silicone resin that is filled into the reflector 22 in the manufacturing process to harden rapidly after filling. As a result, solid silicone resin is formed quickly on the bottom portion of the bowl-shaped reflector 22, thereby plugging any gaps 72. This effectively prevents the silicone resin material that continues to be filled from flowing into the gaps 72. Accordingly, there is no need for a separate step for removing the leaked resin 82a, thereby enabling a commensurate improvement in manufacturing efficiency.

Furthermore, electrical conduction with external devices via the outer leads of the wiring lead 30 is not inhibited since the leaked resin 82a is not deposited on the outer leads. This enables highly reliably performing electric connection with the LED 31 by a method such as solder connection.

Also, preventing the leaking of silicone resin from the gaps 72 enables suppressing the occurrence of voids (air bubbles) in silicone resin in the gaps 72, which result from air present in the gaps 72 to be mixed into the silicone resin. Consequently, the LED device 31 is more reliably sealed with silicone resin.

Note that in order to favorably obtain the aforementioned effects, the region in which the organic coating 120a is provided is, as shown in the enlarged view of portion S7 in FIG. 10B, extended to region L22 which is in the gap 72 between the reflector 22 and the wiring lead 30. This is preferable since, even if the leaked resin 82a flows to some extent into the gap 72, the resin hardens before the leak can expand to a larger scale, thereby preventing any further leaking.

### Second Functional Group C2′

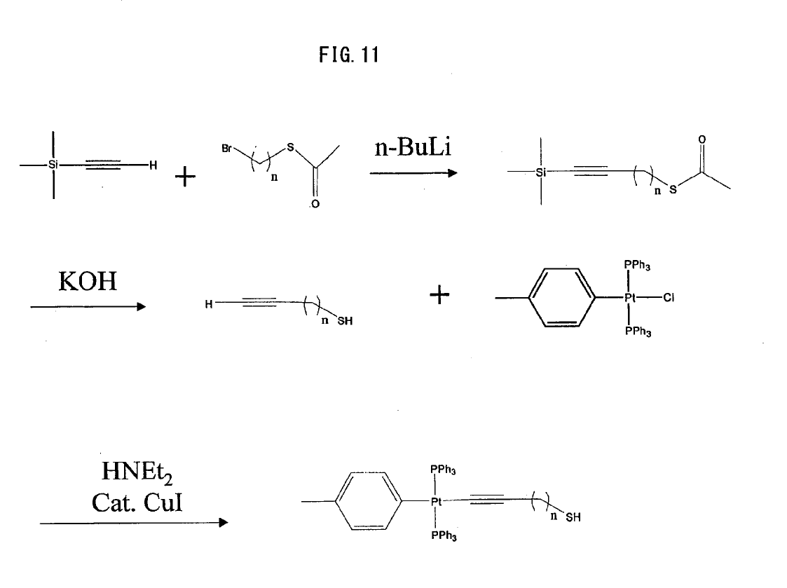

FIG. 11 shows an exemplary synthesis reaction in a case of the functional organic molecules 12a of embodiment 4 having a molecular structure in which the first functional group A2 is a thiol group, the main chain B2 is a methylene chain, and the second functional group C2′ is a platinum complex.

First, a hydrogen bromide elimination and condensation reaction are caused between ethynyltrimethylsilane and acetylsulfide alkane having bromine at one end, in the presence of n-butyllithium.

Next, the acetyl group and trimethylsilane at both ends of the resulting compound are replaced with hydrogen by potassium hydroxide. Furthermore, according to a recitation in the Journal of Organometallic Chemistry, 641 (2002)53-61, a hydrogen chloride elimination and condensation reaction is caused by diethylamine in the presence of trans-para-toluene diphenyl phosphineplatinum chloride complex [trans-(p-tol)(Ph3P)2PtCl] and a copper bromide catalyst. This results in the synthesis of the functional organic molecules 12a.

### Embodiment 5

The following is a description of embodiment 5 focusing on differences from embodiment 4.

An LED device of embodiment 5 has a characteristic feature in that a second functional group C3 of functional organic molecules 13 is a fluorescent or phosphorescent functional group, thereby improving luminous efficiency.

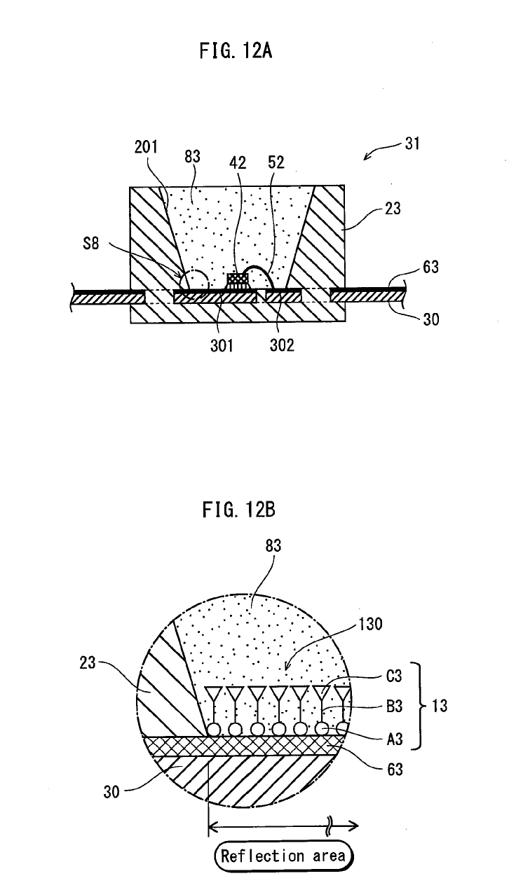

There are cases in which an Ag plating coat 63 (FIG. 12A) is provided for improving reflection over conventional technology in order to effectively use light emitted from the LED chip 42. However, only light with a wavelength of approximately 500 nm or more is effectively reflected by Ag silver materials, and it is difficult to obtain an effective reflection rate for light of shorter wavelengths (e.g., blue light and ultraviolet light with wavelengths of around 380 nm to 500 nm).

In contrast, in the present invention, an organic coating 130 is formed on the Ag plating coat 63 in regions thereof that correspond to the exposed regions 301 and 302 of the wiring lead 30. The organic coating 130 includes functional organic molecules 13 having a structure in which the second functional group C3 converts short wavelength light to fluorescent or phosphorescent light (enlarged view of S8 in FIG. 12B).

This aims to supplement the efficiency with which visible light is reflected by the Ag plating coat 63. The first functional group A3 and main chain B3 are the same as A1 and B1.

Specifically, according to the LED device 31 of embodiment 5 having the above structure, the long wavelength light components (light with wavelengths of approximately 500 nm or greater) of the light emitted by the LED chip 42 during operation is effectively directly reflected toward the front of the chip by the conventional Ag plating coat 63. At this time, the traveling of the long wavelength light is not hindered by the organic coating 130, which due to being a single molecule film only has a single-molecule thickness. The long wavelength light passes through the organic coating 130 and reaches the Ag plating coat 63, and furthermore is reflected by the Ag plating coat 63 without any problems.

On the other hand, short wavelength light (light with a wavelength of approximately 380 to 500 nm) emitted by the LED chip 42 does not pass through the organic coating 130 due to having a higher energy level than long wavelength light. The density of the short wavelength light is most concentrated in a vicinity of the second functional groups C3 of the outward-oriented functional organic molecules 13. Also, the short wavelength light is used as light energy (E=hν) in the second functional group C3, and causes the energy level of the second functional group C3 to move to an excited state (E0→E1).

As a result, the aforementioned light energy (E=hν) ultimately changes to fluorescent or phosphorescent light emitted from the second functional group C3. In other words, The short wavelength light emitted from the LED chip 42 is not actually reflected by the organic coating 130, but rather the light energy (E=hν) of the short wavelength light is used as fluorescent or phosphorescent light, which looks the same as reflected light. As a result, light in both the short wavelength and long wavelength ranges emitted by the LED chip 42 effectively contributes to the luminous efficiency of the LED device 31. This enables the realization of an LED device 31 that is superior to conventional structures.

Note that embodiment 5 is also applicable to a structure in which a plating coat other than the Ag plating coat 63 is used. The light emitting properties of the LED chip 42 can be adjusting by the combination of the visible light directly reflected by the plating coat and the light emitted by the functional group C3. For example, light with a wavelength of approximately 600 nm or greater is effectively reflected if a metal plating coat is used. Therefore, visible light with a wavelength in the region of 600 nm is reflected by the metal plating coat, and light with a wavelength of approximately 600 nm to 700 nm is emitted as red fluorescent or phosphorescent light by the second functional group C3. This has the effect of enabling the realization of an LED device 31 specialized for improving luminance with respect to red light.

### Second Functional Group C3

The second functional group C3 is required to have a fluorescent or phosphorescent light emitting property based on excitation by the aforementioned short wavelength light.

For example, the second functional group C3 may be a compound, chemical structure, or derivative including one or more of a bis styrylbiphenyl derivative or other stilbene derivative, a bis(triazinylamino) stilbene sulfonic acid derivative or other azole-modified stilbene derivative, a coumarin derivative, an oxazole derivative, a pyrazoline derivative, a pyrene derivative, and a porphyrin derivative.

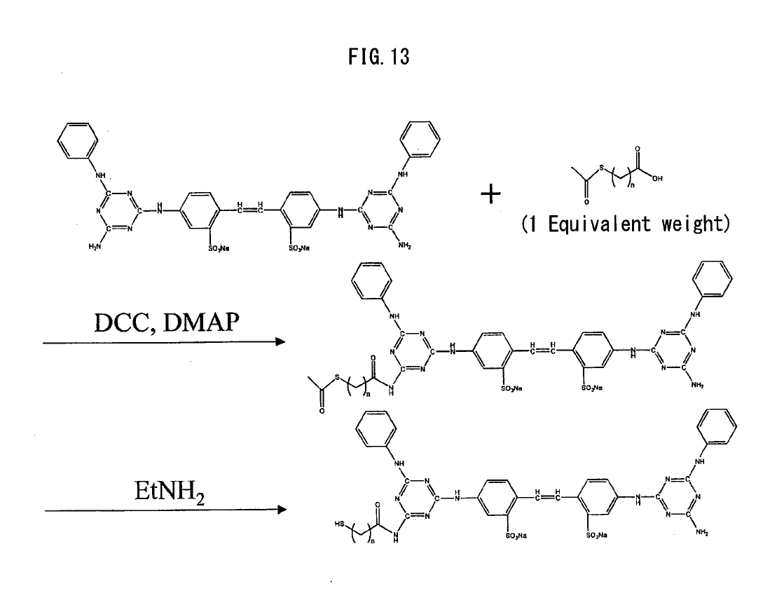

FIG. 13 shows an exemplary synthesis reaction of the functional organic molecules 13 in which the first functional group A3 is a thiol group, the main chain B3 is a methylene chain, and the second functional group C3 is a bis(triazinylamino)stilbene sulfonic acid derivative.

A dehydration and condensation reaction is caused between the bis(triazinylamino)stilbene sulfonic acid derivative and an equivalent weight of methylene acetylsulfide having carboxylic acid at one end in the presence of 1,3-dicyclohexylcarbodiimide (DCC) and 4-dimethylaminopyridine (DMAP). The acetylsulfide portion of the resulting dehydrated and condensate compound is replaced with thiol by ethylamine. This results in obtaining the functional organic molecules 13.

### Embodiment 6

The following is a description of embodiment 6 focusing on differences from embodiment 4.

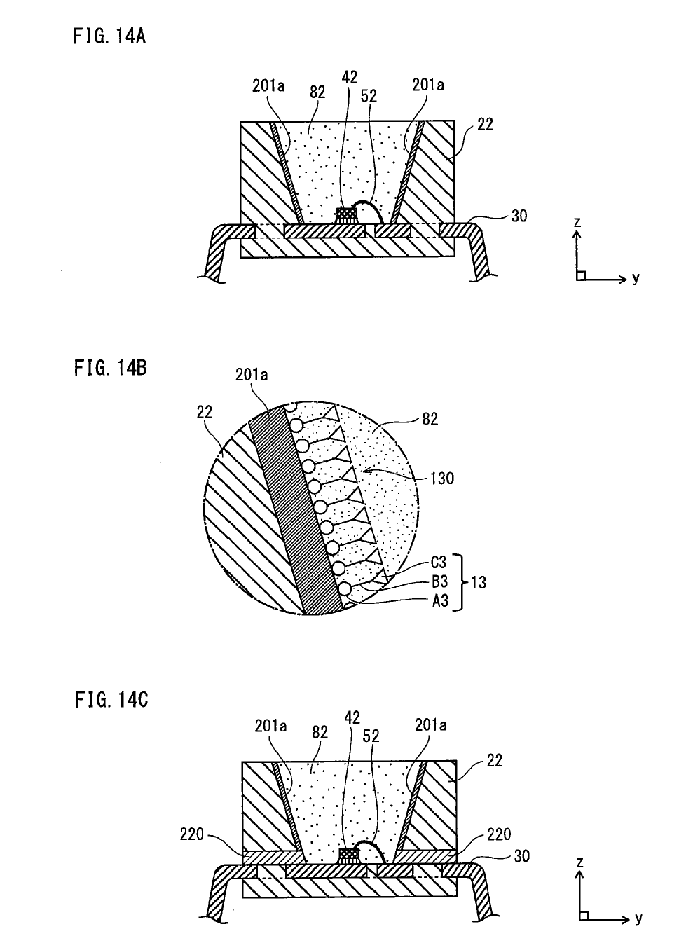

FIG. 14A is a cross-sectional view showing an LED device according to embodiment 6.

Features of the LED device according to embodiment 6 are as follows. This LED device is based on the LED device according to embodiment 4, has an Ag plating coat 201a provided on the surface of the reflector 22, and also has an organic coating 130 provided on the surface of the Ag plating coat 201a. The organic coating 130 is formed by self-assembly of the densely arranged functional organicmolecules 13 according to the present invention.

With the provision of the Ag plating coat 201a, during operation of the LED device, light emitted from the side surfaces of the LED chip 42 is reflected by the Ag plating coat 201a. The reflected light is directed to exit the LED device from the front surface (toward the upward direction as viewed in the figure). Since the Ag plating coat 201a is highly reflective, an excellent luminous efficiency is achieved.

Further, with the provision of the organic coating 130 on the surface of the Ag plating coat 201a, alteration of the Ag plating coat 201a is prevented even if the Ag plating coat 201a is exposed to unnecessary gas at the time of manufacturing the LED device. Consequently, good reflectivity is maintained.

Generally, an Ag material is highly chemically reactive and thus easily reacts with various corrosive gases (for example, various components present in the thermoplastic resin material of the reflector 22) contained in the atmosphere at the time of manufacturing process or with a catalyst (such as platinum group catalyst) that is necessary for addition polymerization of the silicone resin constituting the sealing resin 82. In addition, even after manufacturing of the LED device is completed, the Ag material tends to react with a corrosive gas (such as hydrogen sulfide) present in the atmosphere since the gas permeability of the silicone sealing resin is extremely high. If Ag reacts with such a corrosive gas or catalyst, the Ag plating coat undergoes discoloring or tarnishing so that the reflectivity may become lower than the designed level. In such a case, even if the light emitting performance of the LED chip 42 is sufficient, the Ag plating coat cannot sufficiently reflect the emitted light. As a result, a problem arise that the overall luminance of the device decreases and thus the luminous efficiency decreases.

Similar problem of a decrease of the luminous efficiency caused by a reaction of a plating coat with a corrosive gas or a catalyst may occur even if the plating coat is made of a material other than Ag.

In view of the above risks and problems, the LED device 31 according to embodiment 6 is provided with the organic coating 130 disposed on the surface of the Ag plating coat 201a. The organic coating 130 is composed of the functional organic molecules 13 that are precisely arranged. Therefore, even if a corrosive gas or a catalyst is present in the atmosphere at the time of manufacturing, the organic coating 130 serves as protection of the Ag plating coat 201a, so that direct contact between the Ag plating coat 201a and a corrosive gas is avoided. Consequently, unnecessary chemical change of Ag is prevented, so that the Ag plating coat 201a maintains an excellent reflectivity and thus an LED device with good luminous efficiency is achieved.

In addition, by virtue of the excellent reflectivity of the Ag plating coat, light emitted by the LED chip 42 is used with improved efficiency, which leads to reduce the risk that wasteful output accumulates as latent heat at locations around the Ag plating coat. That is, the LED device according to embodiment 6 achieves excellent luminous efficiency, increases longevity by preventing the LED chip 42 from damage caused by overheating, and is advantageous for achieving compact packaging of the device.

In addition, the functional organic molecules 13 according to embodiment 5 may be used as the functional organic molecules of embodiment 6. Then, the second functional group C3 of each functional organic molecule may use a fluorescent or phosphorescent functional group. As a result, out of the overall light emitted by the LED chip 42, shorter wavelength light, which is higher in energy level, is effectively used, thereby further improving luminous efficiency. Alternatively, in favor of the adhesion with the sealing resin 82 (silicone resin, for example) filled into the reflector 22, the functional organic molecules 12 according to embodiment 3 may be used. It is also applicable to use both the functional organic molecules 12 and 13 in mixture.

Regarding the device according to embodiment 6, one example of a method of forming the organic coating is to coat the organic molecules 12 on the Ag plating coat 201a by selectively masking the other surface. In another example, the reflector 22 is made of a metallic material and separately from the wiring lead 30, as shown in FIG. 14C. Then, the Ag plating coat 201a is formed by conducting electrodeposition on a predetermined portion of the reflector. Then, the Ag plating coat 201a is immersed in a predetermined dispersion fluid as shown in FIG. 5 to form organic coating 130 on the entire surface. Then, the reflector 22 is fixed to the wiring lead 30 with an insulating adhesive resin 220 (which may be a resin or ceramics) to prevent shoring between the reflector 22 and the wiring lead 30. In this case, the organic coating 130 is formed to cover a relatively wide region except, for the Ag plating coat 201a. Yet, this gives no problem in the resulting LED device.

### Remarks about Embodiments 1 to 6

The following additional effects can be achieved if the organic coating 110 etc. of the present invention is formed on the surface of the die pad and the wiring lead.

In order to improve adhesion with resin (e.g., epoxy resin), there are cases in which roughening processing is performed on the surface of the wiring lead in a semiconductor device such as an IC, LSI, etc. to create better cling with the resin.

Also, an appearance examination is performed for quality management of the semiconductor device to be manufactured. Generally, such an examination is performed by a laser measurement method using a laser emitting apparatus and a light receiving device. However, the irradiated laser is unnecessarily diffusely reflected off of the roughened surface, and it can be difficult to get accurate measurements due to a reduction in the amount of light received by the light receiving device or the reception of unnecessary light. This problem becomes significant when an outward appearance is examined at a microscopic level using a weak laser.

In response to this problem, if the organic coating of the present invention is formed on the roughened surface of the die pad and the wiring lead, the functional organic molecules absorb the laser light, convert the energy to fluorescent or phosphorescent light, and emit the fluorescent or phosphorescent light. This enables preventing diffuse reflection of the laser light due to unevenness in the rough surface. It is therefore possible to efficiently and accurately perform the appearance examination step, and also to improve manufacturing efficiency for the semiconductor device.

Regarding the LED device, a conductive paste containing silicone resin (a die bonding agent such as an Ag paste) may be useable as the sealing resin, instead of a 100% silicone resin. By performing die bonding using the silicone resin containing conductive paste, the LED chip 42 is securely bonded to the wiring lead 30. In addition, the silicone resin containing conductive paste undergoes less degradation as compared with a conventional conductive past containing epoxy resin, so that the stabilization of electrical and thermal conductivity is duly expected.

Regarding Ag particles present in the Ag paste, the organic coating according to the present invention may be provided to coat the surfaces of the particles. With the provision of the organic coating, the Ag particles are prevented from making direct contact with platinum catalyst which is for addition polymerization of the silicone resin, or with unnecessary corrosive gas, so that alteration and discoloring of the Ag particles are suppressed. Consequently, the sealing resin 82 is maintained highly transparent, so that decrease in luminance is suppressed and appropriate operation of the LED device is ensured over a long period of time.

### Embodiment 7

The following describes embodiment 7 of the present invention.

Embodiment 7 pertains to film carrier tape such as TAB (Tape Automated Bonding) tape, T-BGA (Tape Ball Grid Array) tape, and ASIC (Application Specific Integrated Circuit) tape, which is used in the implementation of electrical parts of the IC, LSI, etc., and in particular to technology for improving the adhesion of a solder resist layer formed on the film carrier tape.

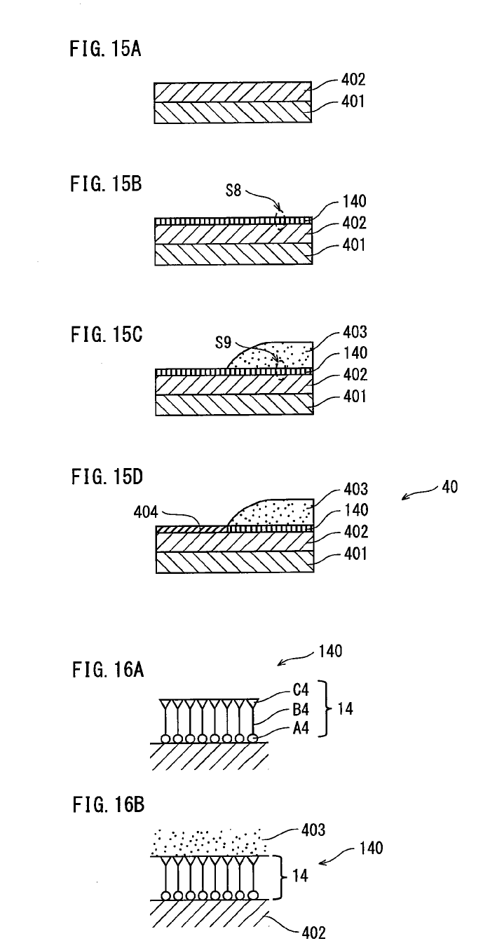

FIGS. 15A to 15D are schematic cross-sectional views showing a manufacturing process for a film carrier tape 40 of embodiment 7.

As shown in FIG. 15D, The film carrier tape 40 is constituted from an insulation film 401 composed of a polyimide or the like, a wiring pattern layer 402 composed of Cu, and a solder resist layer 403 that have been laminated in the stated order.

The insulation film 401 and the solder resist layer 403 are constituted from an insulating resin material (e.g., a polyimide series, epoxy series, or urethane series resin), and are provided as insulation for preventing short-circuits of the wiring pattern layer 402.

An Sn plating layer 904 has been formed on the surface of the wiring pattern layer 402 for connection with implementation parts by soldering. An Sn material is preferable due to having solder wettability, flexibility, and lubricating properties, and being able to form a plating layer 404 suitable for use in the film carrier tape.

When forming the Sn plating layer 404 in the film carrier tape 40, the insulation film 401, the wiring pattern layer 402, and the solder resist layer 403 are first laminated in the stated order, and an electrolytic plating method step or the like is used to form an Sn plating coat by immersing the intermediate product in an Sn plating tank filled with an Sn plating fluid (e.g., an Sn-containing compound dissolved in BF4 solvent) that has been heated to a predetermined temperature. The Sn plating layer 404 is selectively formed on the wiring pattern layer 402 due to tin component's property of not adhering to the insulating material.
Here, a characteristic feature of embodiment 7 is that prior to the Sn plating step, an organic coating 140 has been formed on the wiring pattern layer 102 by the self-assembly of functional organic molecules 14. As shown in FIG. 15E, each of the functional organic molecules 14 has a structure including a main chain B4, a first functional group A4 at one end of the main chain B4, and a second functional group at the other end of the main chain B4. The first functional group A4 has a metal bonding property, and the second functional group C4 is a functional group having a high degree of adhesion to the solder resist layer 403 (e.g., a compound, chemical structure, or derivative including one or more of a phthalic anhydride, a pyromellitic acid dianhydride or other acid anhydride, and a primary amine compound). The main chain B4 may be composed of a glycol chain alone or of a glycol chain and at least one selected from a methylene chain, a fluoromethylene chain, and a siloxane chain.

The wiring pattern layer 402 and the solder resist layer 403 are securely adhered together via the organic coating 140, and edges of the solder resist layer 403 do not peel off of the wiring pattern layer 402 even during the Sn plating step involving immersion in the Sn plating tank heated to the predetermined temperature. This has the effects of preventing peeling of the solder resist layer 403, and enabling the formation of a favorable Sn plating layer 404.

Embodiment 7 also has the effects of suppressing the formation of a so-called internal battery on the wiring pattern layer 402, and preventing corrosion of the surface thereof. The following describes the pertaining principle with use of the schematic enlarged view of FIG. 24A showing a vicinity of the wiring pattern layer 402 and the solder resist layer 403 during the plating step.

The solder resist layer 403 and the wiring pattern layer 402 experience thermal contraction and internal stress during hardening of the solder resist, due to the unique linear expansion coefficients of the materials of the layers.

Here, given that the plating fluid in the plating tank is heated to approximately 60° C., when the wiring pattern layer 402 having the solder resist layer 403 formed thereon is inserted in the plating fluid, the solder resist layer 403, which has higher internal stress than metal, experiences a relatively large degree of thermal expansion. Accordingly, an edge 403x of the solder resist layer 403, which is most easily influenced by thermal contraction forces, is pulled by the influence of the internal stress, and peels up off of the surface of the wiring pattern layer 402. The edge 403x then further lifts up due to remaining internal stress than metal in the solder resist layer 403 since the plating fluid enters between the edge 403x and the wiring pattern layer 402. A solvent region 500 composed mainly of the solvent of the plating fluid and sparsely including Sn ions is formed between the raised edge 403x and the wiring pattern layer 402.

A concentration gradient with respect to the Sn component of the plating fluid occurs in the solvent region 500 and an adjacent region 501 in the proximity thereof. Also, due to differences in the ionization tendencies of Sn and Cu, Cu ions from the surface of the wiring pattern layer 402 seep into the solvent in the solvent region 500 which has a sparse amount of Sn ions. Electrons that are released from the wiring pattern layer 402 when the Cu ions appear are received by the Sn ions in the plating fluid, and a deposition layer 408 composed of deposited Sn is formed on the wiring pattern layer 402 in an region directly below the edge 403x of the solder resist 403. As shown in FIG. 24A, a so-called localized battery is formed due to a series of oxidation-reduction reactions between the Sn ions and the Cu ions (see Japanese Patent No. 2076342 for details of the formation process for the localized battery).

As the localized battery reaction progresses even further, the portion into which the Cu ions seeped becomes a corroded region 406. The corroded region 406 thereafter remains hidden from sight underneath the edge 403x(FIG. 24B). The corroded region 406 does not stand out visually, but failures such as ruptures in the film carrier tape can originate at the corroded region 406 when there are pulling forces etc. during manufacturing steps that use the film carrier tape.

In contrast, in the present invention, given that the solder resist layer 403 and the wiring pattern layer 402 are securely adhered by the organic coating 140, the edge 403x does not peel off of the wiring pattern layer 402 even if, for example, there is some degree of internal stress in the solder resist layer 403 with respect to the wiring pattern layer 402 during the plating step. The formation of the corroded region 406 can therefore be avoided since the solder resist layer 403 does not peel off of the wiring pattern layer 402. Also, although the solder resist layer 403 experiences thermal expansion when inserted into the plating tank, the internal stress can be eliminated by performing post-processing such as ordinary anneal processing after the plating step, thereby eliminating stress damage to the solder resist layer 403. Accordingly, embodiment 7 enables the formation of a favorable Sn plating layer 404, and furthermore enables the realization of a film carrier tape with superior mechanical strength.

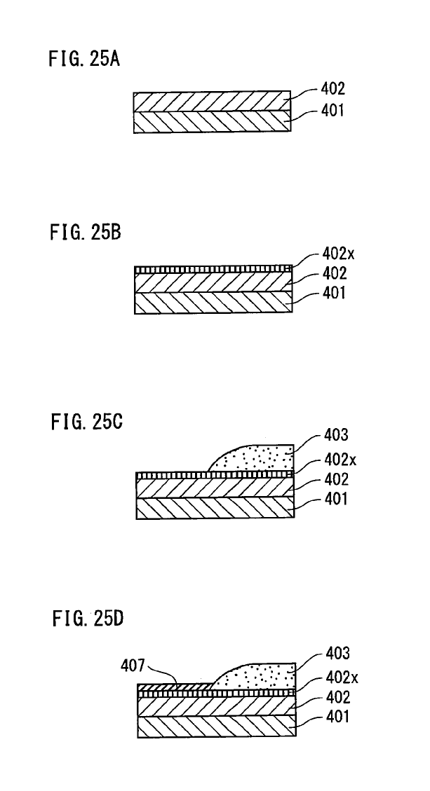

Note that Japanese Patent No. 3076342 discloses technology for preventing the formation of the corroded region 406 by, as shown in FIGS. 25A to 25D, forming a first Sn plating layer 402x including a Cu component on the surface of the wiring pattern layer 402 before the provision of the solder resist layer 403, and thereafter forming the solder resist layer 403 and a second Sn plating layer 407. However, the present invention has significant differences from the aforementioned patent in that there is no need to perform the plating step twice, which shortens the manufacturing process and reduces the amount of plating fluid used and drainage thereof, thereby having the effect of reducing manufacturing costs and alleviating environmental problems.

### Manufacturing Method

The following describes a manufacturing method for the film carrier tape 40 of embodiment 7.

First, the predetermined wiring pattern layer 402 (Cu foil) is formed on the insulation film 401 using a photoetching method or the like (FIG. 15A).

Next, in the organic coating formation step, the organic coating 140 composed of a single molecule film is formed by the self-assembling effect of the functional organic molecules 14 deposited on the wiring pattern layer 402 (FIG. 15B, enlarged portion S8 of FIG. 16A).

Then, in the solder resist layer formation step, the solder resist layer 403 is formed by applied a solder resist material paste to the organic coating 140 using a printing method or the like (FIG. 15C). At this time, the second functional group C4 causes the solder resist material to harden, thereby forming a chemical bond therebetween (enlarged portion S9 of FIG. 16B).

Then, the organic coating 140 in regions other than the formation region of the solder resist layer 403 is removed. Note that masking may be performed in the regions other than the formation region of the solder resist layer 403 in place of performing the removal processing.

Then, the Sn plating layer is formed in the predetermined region on the wiring pattern layer 402 by immersion of the organic coating 140 and the resist layer 403 in the Sn plating tank (FIG. 16D). The Sn plating layer is formed only on conductive material surfaces by using an electroless substitution plating method.

This completes the formation of the film carrier tape 40.

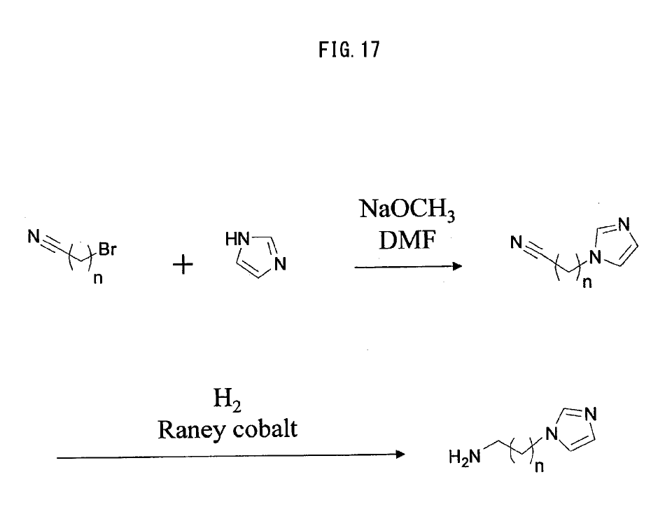

FIG. 17 shows an exemplary synthesis reaction process of the functional organic molecule of embodiment 7, in which the first functional group A4 is an imidazole group, the main chain B4 is a methylene chain, and the second functional group C4 is an amine.

The synthesis occurs according to the heretofore known recitation of the Journal of Medicinal Chemistry, 1987, 30, 185-193. Imidazole alkanenitrile is synthesized by forming a mixed solvent including dimethylformamide (DMF) and sodium methoxide doped with imidazole, and adding bromoalkanenitrile dissolved in DMF. The resulting compound is distilled and dissolved in a mixed solvent including methanol and trimethylamine, and a Reney cobalt catalyst is used to cause a hydrogen addition reaction with respect to the nitrile group. This completes the synthesis of the functional organicmolecules.

### Embodiment 8

The following describes a film carrier tape 40 of embodiment 8, focusing on differences from embodiment 7.

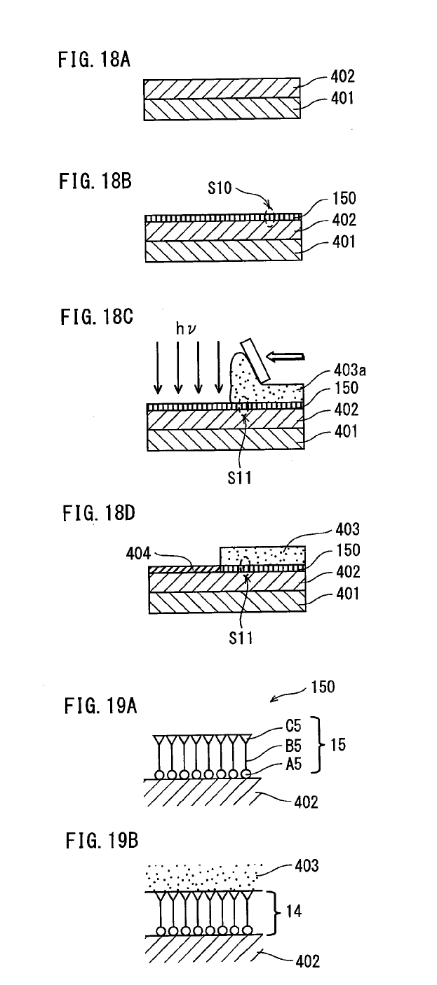

A characteristic feature of the film carrier tape 70 according to Embodiment 8 and shown in FIG. 18D is that the wiring pattern layer 402 and the solder resist layer 403 have been bonded together using functional organic molecules 15 that include a second functional group C5 having a photopolymerization initiating property or a photosensitive property (enlarged view of S11 in FIG. 19A).

The second functional group C5 is composed of, for example, a compound, chemical structure, or derivate including at least one of a benzophenone, an acetophenone, an alkylphenone, a benzoin, an anthraquinone, a ketal, a thioxanthone, a coumarin, a triazine halide, an oxadiazole halide, an oxime ester, an acridine, an acridone, a fluorenone, a fluorane, an acylphosphine oxide, a metallocene, a polynuclear aromatic, a xanthene, a cyanine, a squalium, an acridone, a titanocene, and a tetra-alkyl thiuram sulfide. Also, the second functional group C5 is not limited to these compounds. Any compound may be applied as long it has a photo-excited polymerization initiating property or a photosensitive property.

Embodiment 8, which uses the functional organic molecules 15 has the same effect as embodiment 7, that is to say, preventing the peeling of the solder resist layer 403 from the wiring pattern layer 402.

Additionally, the application of the solder resist material while exciting a photopolymerization initiating agent quickly hardens the material to form the solder resist layer. This prevents dripping and loss of resin shape, and enables the formation of the solder resist layer 403 with an accurate and precise pattern.

Specifically, the solder resist material paste used in the application step is provided in a fluid state set to a predetermined viscosity. The paste is applied along a pattern mask disposed on the wiring pattern layer 402. The mask is removed after performed predetermined drying, but there is still the possibility of some of the paste spreading after removal of the mask. For this reason, a degree of spreading is assumed, and the paste is applied to an region that is somewhat smaller than the patterning mask. Here, the edges of the paste form acute angles and readily peel off during the plating step.

In contrast, in embodiment 8, the organic coating is exposed to ultraviolet radiation directly before application of the paste, thereby providing the second functional group C5 with light energy (E=hν), which enables causing the paste to harden quickly. This eliminates the formation of acutely angled edges, such as in conventional technology. The paste can be applied accurately to the patterning mask since there is little flow in the paste. This has the benefit of enabling the formation of a solder resist layer with a highly precise shape.

### Manufacturing Method

First, the predetermined wiring pattern layer 402 (Cu foil) is formed on the insulation film 401 using a photoetching method or the like (FIG. 18A).

Next, the organic coating 140 composed of a single molecule layer (i.e., monomolecular layer) is formed by the self-assembly of the functional organic molecules 15 that have been deposited on the wiring pattern layer 402 (FIG. 18B, enlarged view of S10 in FIG. 19A).

Then, the second functional groups C5 of the functional organic molecules 15 in the organic coating 140 are exposed to ultraviolet radiation of a predetermined wavelength (e.g., approximately 340 nm or greater). This moves the second functional groups C5 from their base state to an excited state (E0→E1). The paste material for forming the solder resist layer is applied in a predetermined thickness using a blade BL during a predetermined period in which the excited is maintained (FIG. 18C). Accordingly, the excitation energy of the second functional groups C5 is transferred to the solder resist side as thermal energy, thereby causing thermosetting of the solder resist.

This completes the manufacture of the film carrier tape 40 (FIG. 18D).

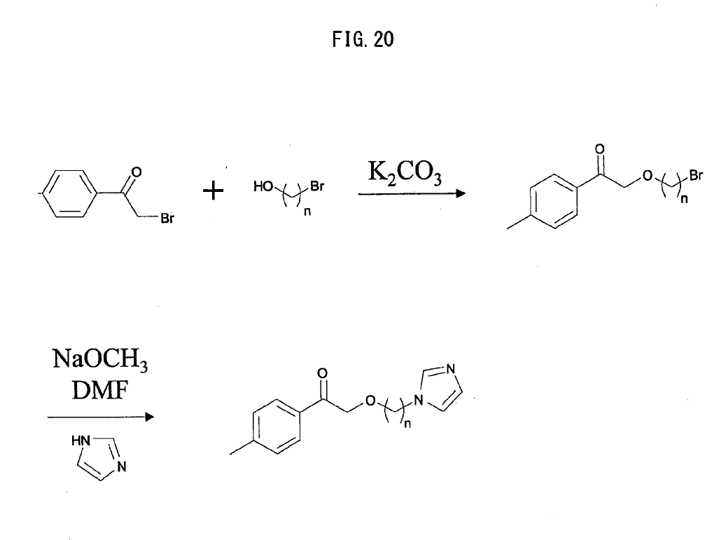

FIG. 20 shows an exemplary synthesis reaction process of the functional organic molecule of embodiment 8, in which the first functional group A5 is an imidazole, the main chain B5 is a methylene chain, and the second functional group C5 is a methylacetophenone.

Methylacetophenone having bromide at one end is reacted with linear alkane having a hydroxyl at one end and bromide at the other end, in the presence of potassium carbonate, thereby causing an ether bond with the linear alkane due to a hydrobromide elimination reaction of the methylacetophenone. Thereafter, the resulting compound is added to a mixed solvent including DMF and sodium methoxide containing an imidazole, and the functional organic molecules are synthesized by a de-hydrobromidating condensation reaction.

### Embodiment 9

The following is a description of embodiment 9 focusing on differences from embodiments 7 and 8.

In embodiment 9, the organic coating is formed on the wiring pattern layer 402 using the functional organic molecules 15 that are the same as in embodiment 2. A characteristic feature of embodiment 9 is that a batch process is used when forming the solder resist layer 403. This has the benefits of, similarly to embodiment 8, strengthening the bond between the solder resist layer 403 and the wiring pattern layer 402, as well as creating a wider range of possible thicknesses for the solder resist layer 403 than when using a general printing method. This enables flexibly responding to modifications in design.

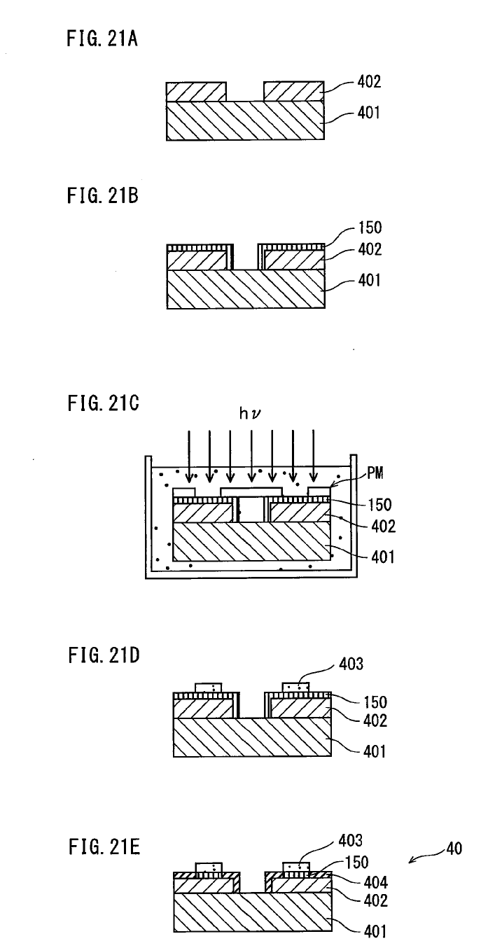

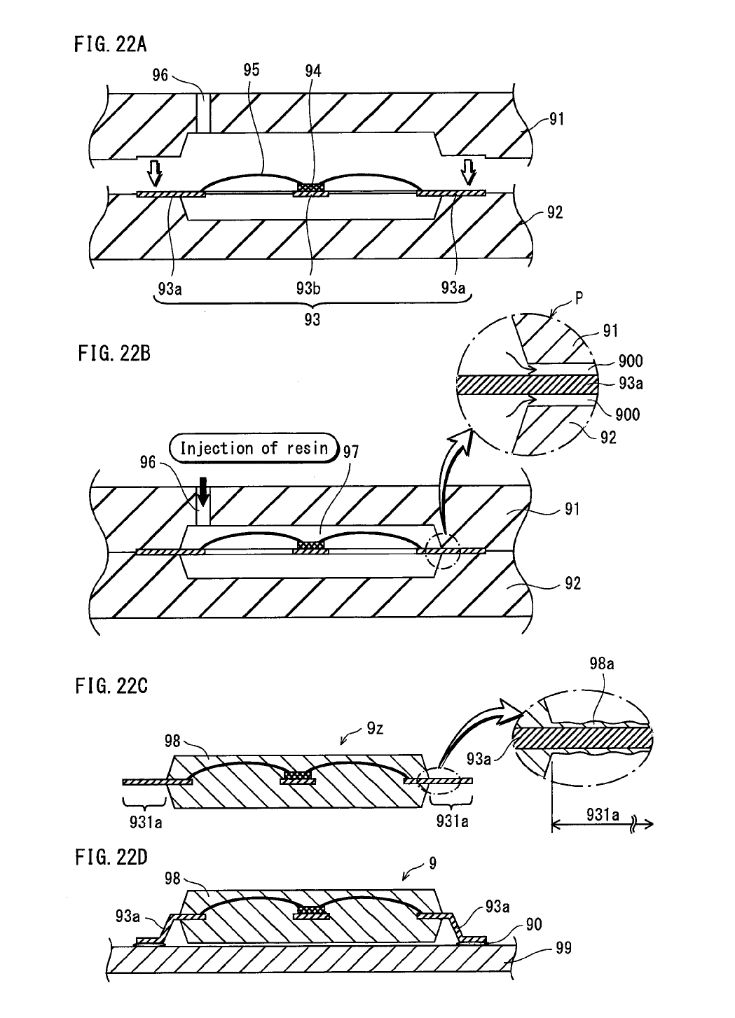

FIGS. 21A to 21E show a manufacturing process for the film carrier tape 40 of embodiment 9.

First, the wiring pattern layer 402 is formed in a predetermined pattern on the insulation film 401 (FIG. 21A).

Next, in the organic coating formation step, the organic coating 150 is formed on the surface of the wiring pattern layer 402, thereby obtaining an intermediate product (FIG. 21B). The formation method can be performed in substantially the same way as in embodiment 1.

Then, a resin dispersion fluid is prepared by dispersing a photopolymerizing compound, which is to form the solder resist material, in a solvent. The photopolymerizing compound is a monomer and/or an oligomer such as a compound containing, within the molecules, an acrylate group, a methyacrylate group, an acrylamide group, a urethane group, an isocyanate group, or a vinyl group.

After preparation, the resin dispersion fluid is filled into a batch of a predetermined solution. A pattern mask PM corresponding to an region where the solder resist is to be formed is applied to the intermediate product. The pattern mask PM can be, for example, a photoresist layer formed by heretofore known exposure processing. The intermediate product is immersed in the batch of resin dispersion fluid, and exposed to ultraviolet radiation while keeping the intermediate product in a stable condition in the fluid (FIG. 21C).

This realizes the solder resist layer formation step. Specifically, the photopolymerizing compound dispersed in the fluid polymerizes around the second functional groups C5, which are photopolymerization initiating agents, in the vicinity of the organic coating 50 in the apertures of the pattern mask PM (or in pattern gaps if a photoresist layer is used). Given that progression of the polymerization reaction originates at positions nears the second functional groups C5, a solder resist layer 403 with a single-molecule thickness can be formed by making the ultraviolet radiation exposure time very short. Also, making the ultraviolet radiation exposure time longer theoretically causes the formation of a solder resist layer with a thickness corresponding to the depth of the second functional groups C5. This method enables the adjustment of the solder resist layer 403 to an arbitrary thickness.

Note that the thickness of the solder resist layer 403 can be controlled not only according to the ultraviolet radiation exposure time, but also by adjusting the concentration of compounds in the dispersion fluid.

After the ultraviolet radiation hardening reaction, the intermediate product is removed from the batch, the mask is removed, and appropriate cleaning is performed (FIG. 21D).

Thereafter, the organic coating 150 is removed from regions other than below the solder resist layer 403, and the Sn plating layer 404 is formed (FIG. 21E).

This completes the manufacture of the film carrier tape 40.

According to this manufacturing method, the solder resist material is buoyant due to the difference in specific gravity from the dispersion fluid, thereby enabling the formation of the solder resist layer 403 on the organic coating 150 without a loss of shape due to gravity. This has the benefit of enabling freely forming a thick-film or thin-film solder resist layer 403 with precision of shape and thickness.

Note that it is preferable to adjust the specific gravity of the dispersion fluid such that the photopolymerizing compound favorably disperses therein for a predetermined time period. Furthermore, if the specific gravity of the dispersion fluid is adjusted such that the photopolymerizing compound gradually settles, it is possible to prevent unnecessary limitations on the reaction rate due to localized shortages of the photopolymerizing compound.

### Other Remarks

Although the organic coating is constituted from a single molecule film by self-assembling functional organic molecules in the above-described embodiments, the organic coating may be multilayered as long as there is no degradation in the degree of adhesion to the substrate etc. of the semiconductor device.

In this case, a bonding property is required for the second functional groups and first functional groups of adjacent molecules between a first layer and a second layer composed of the functional organic molecules. In other words, it is necessary for the first functional group to be a compound or structure that has a metal bonding property for the wiring lead, die pad, etc., as well as a bonding property for the second functional group.

The present invention can applied to a film carrier tape used in a semiconductor device such as an IC, LSI, or VLSI that is packaged in a resin sealing, in an LED device implementing an LED element used in an LED lighting apparatus etc., in a flexible substrate, or the like.

### INDUSTRIAL APPLICABILITY

The present invention can applied to a film carrier tape used in a semiconductor device such as an IC, LSI, or VLSI that is packaged in a resin sealing, in an LED device implementing an LED element used in an LED lighting apparatus etc., in a flexible substrate, or the like.

1. A manufacturing method for a resin-coated metal part, comprising the steps of:
forming an organic coating by (i) depositing a material containing a plurality of functional organic molecules on a wiring lead composed of a metallic material, each of the functional organic molecules having a main chain, a first functional group having a metal bonding property, and a second functional group having a predetermined property, the first functional group and the second functional group each being provided at a different end of the main chain, and (ii) causing the plurality of functional organic molecules to self-assemble by bonding of the first functional groups to metal atoms of the wiring lead; and
adhering a resin to a predetermined surface region of the wiring lead having the organic coating formed thereon, the adhering step being performed after the organic coating formation step,
wherein each of the functional organic molecules used in the organic coating formation step has the main chain composed of at least one selected from the group consisting of a methylene chain, a fluoromethylene chain, a siloxane chain, and a glycol chain.

2. The manufacturing method according to claim 1,
wherein the first functional group of each of the functional organic molecules is a compound, a chemical structure, or a derivative having at least one selected from the group consisting of a thiol compound, a sulfide compound, and a nitrogen-containing heterocyclic compound.

3. The manufacturing method according to claim 1,
wherein the resin is a thermosetting resin.

4. The manufacturing method according to claim 3,
wherein the thermosetting resin is a compound, a chemical structure, or a derivative having at least one selected from the group consisting of an epoxy resin, a phenol resin, an acryl resin, a melamine resin, a urea resin, an unsaturated polyester resin, an alkyd resin, a polyimide resin, a polyamide resin, and a polyether resin, and
wherein each second functional group is a compound, a chemical structure, or a derivative having at least one selected from the group consisting of a hydroxyl, a carboxylic acid, an acid anhydride, a primary amine, a secondary amine, a tertiary amine, an amide, a thiol, a sulfide, an imide, a hydrazide, an imidazole, a diazabicyclo-alkene, an organic phosphine, and a boron trifluoride amine complex.

5. The manufacturing method according to claim 3,
wherein, in the organic coating formation step, the organic coating is formed to cover a surface region of the wiring lead that is greater in area than the predetermined surface region of the wiring lead where the resin is to be adhered in the resin adhering step.

6. The manufacturing method according to claim 3,
wherein the thermosetting resin is a silicone resin or a silicone resin modified with at least either of an epoxy group and an alkoxysilyl group, and
wherein each second functional group is a compound, a chemical structure, or a derivative having at least one selected from the group consisting of a vinyl group, an organohydrogensilane, a hydroxyl, an acid anhydride, a primary amine, and a secondary amine.

7. The manufacturing method according to claim 3,
wherein the thermosetting resin is a silicone resin, and
wherein each second functional group is a compound, a chemical structure, or a derivative having at least one selected from the group consisting of platinum, palladium, ruthenium, and rhodium.

8. The manufacturing method according to claim 3,
wherein each second functional group is a compound, a chemical structure, or a derivative having at least one selected from the group consisting of a fluorescent compound and a phosphorescent compound.

9. The manufacturing method according to claim 1,
wherein the organic coating formation step includes the substeps of:
preparing an organic molecule dispersion fluid by dispersing the plurality of functional organic molecules in a solvent; and
immersing the wiring lead in the organic molecule dispersion fluid so that an immersed surface region of the wiring lead is greater in area than the predetermined surface region of the wiring lead where the resin is to be adhered.

10. A manufacturing method for a semiconductor device, comprising:
the steps of the resin-coated metal part manufacturing method of claim 1; and
the step of electrically connecting the wiring lead to a semiconductor element,
wherein the connecting step is performed between the organic coating formation step and the resin adhering step, and
wherein in the resin adhering step, the resin is molded so that the semiconductor element is encapsulated in the resin and that a portion of the wiring lead is externally exposed.

11. A manufacturing method for a resin-coated metal part, comprising the steps of:
forming an organic coating by (i) depositing a material containing a plurality of functional organic molecules on a wiring lead composed of a metallic material, each of the functional organic molecules having a main chain, a first functional group having a metal bonding property, and a second functional group having a predetermined property, the first functional group and the second functional group each being provided at a different end of the main chain, and (ii) causing the plurality of functional organic molecules to self-assemble by bonding of the first functional groups to metal atoms of the wiring lead; and
adhering a thermosetting resin to a predetermined surface region of the wiring lead having the organic coating formed thereon, the adhering step being performed after the organic coating formation step,
wherein the thermosetting resin used in the adhering step is a silicone resin or a silicone resin having at least either of an epoxy group and an alkoxysilyl group, and
wherein each second functional group used in the organic coating formation step is a compound, a chemical structure, or a derivative having at least one selected from the group consisting of a vinyl group, an organohydrogensilane, a hydroxyl, an acid anhydride, a primary amine, and a secondary amine.

12. The manufacturing method according to claim 11,
wherein in the organic coating formation step, the main chain is at least one selected from the group consisting of a methylene chain, a fluoromethylene chain, and a siloxane chain, and
wherein each first functional group is a compound, a chemical structure, or a derivative having at least one selected from the group consisting of a thiol compound, a sulfide compound, and a nitrogen-containing heterocyclic compound.

13. The manufacturing method according to claim 11,
wherein the organic coating formation step includes the substeps of:
preparing an organic molecule dispersion fluid by dispersing the plurality of functional organic molecules in a solvent; and
immersing the wiring lead in the organic molecule dispersion fluid so that an immersed surface region of the wiring lead is greater in area than the predetermined surface region of the wiring lead where the resin is to be adhered.

14. A manufacturing method for a semiconductor device, comprising:
the steps of the resin-coated metal part manufacturing method of claim 13; and
the step of electrically connecting the wiring lead to a semiconductor element,
wherein the connecting step is performed between the organic coating formation step and the resin adhering step, and
wherein in the resin adhering step, the resin is molded so that the semiconductor element is encapsulated in the resin and that a portion of the wiring lead is externally exposed.

15. A wiring member comprising:
a wiring lead composed of a metallic material; and
an organic coating disposed to cover a surface region of the wiring lead, the organic coating being composed of a plurality of self-assembled functional organic molecules,
wherein each of the functional organic molecules has a chemical structure having a main chain, a first functional group, and a second functional group, the first functional group and the second functional group each being provided at a different end of the main chain, the first functional group being in a form for bonding to the wiring lead by any one or more of a metal bond, a hydrogen bond, and a coordinate bond by a metal complex, and the second functional group having a resin hardening property or a resin-hardening promoting property,
wherein the main chain of each of the functional organic molecules is (i) a glycol chain or (ii) a glycol chain and at least one selected from the group consisting of a methylene chain, a fluoromethylene chain, and a siloxane chain, and
wherein each of the first functional groups has bonded to the wiring lead.

16. The wiring member according to claim 15,
wherein the first functional group of each of the functional organic molecules is a compound, a chemical structure, or a derivative having at least one selected from the group consisting of a thiol compound, a sulfide compound, and a nitrogen-containing heterocyclic compound.

17. A resin-coated metal part, comprising:
the wiring member of claim 15 having a resin material adhered to a surface region thereof,
wherein the surface region of the wiring lead covered by the organic coating is greater in area than the surface region of the wiring member where the resin material is adhered.

18. The resin-coated metal part according to claim 17, further comprising:
a reflector having a bowl-shaped surface for receiving an LED chip to be mounted on the wiring member;
an Ag plating coat disposed to cover a surface of the reflector; and
another functional organic coating disposed to cover a surface of the Ag plating coat, each first functional group of functional organic molecules of said another functional organic coating has bounded to the Ag plating coat.

19. An LED device comprising:
the resin-coated metal part of claim 18;
an LED chip mounted on the wiring member in a manner to be received within the reflector; and
a transparent resin filling an interior of the reflector.

20. The resin-coated metal part according to claim 17, further comprising:
a reflector having a bowl-shaped surface for receiving an LED chip to be mounted on the wiring member,
wherein the reflector is composed of a thermoplastic resin.

21. An LED device comprising:
the resin-coated metal part of claim 20;
an LED chip mounted on the wiring member in a manner to be received within the reflector; and
a transparent resin filling an interior of the reflector.

22. The LED device according to claim 21,
wherein the transparent resin contains a hydrophilic additive mixed therein.

23. The resin-coated metal part according to claim 17,
wherein the resin is a thermosetting resin.

24. The resin-coated metal part according to claim 23,
wherein the thermosetting resin is a compound, a chemical structure, or a derivative having at least one selected from the group consisting of an epoxy resin, a phenol resin, an acryl resin, a melamine resin, a urea resin, an unsaturated polyester resin, an alkyd resin, a polyimide resin, a polyamide resin, and a polyether resin, and
wherein each second functional group is a compound, a chemical structure, or a derivative having at least one selected from the group consisting of a hydroxyl, a carboxylic acid, an acid anhydride, a primary amine, a secondary amine, a tertiary amine, an amide, a thiol, a sulfide, an imide, a hydrazide, an imidazole, a diazabicyclo-alkene, an organic phosphine, and a boron trifluoride amine complex.

25. The resin-coated metal part according to claim 23,
wherein the thermosetting resin is a silicone resin or a silicone resin having at least either of an epoxy group and an alkoxysilyl group, and
wherein each second functional group is a compound, a chemical structure, or a derivative having at least one selected from the group consisting of a vinyl group, an organohydrogensilane, a hydroxyl, an acid anhydride, a primary amine, and a secondary amine.

26. The resin-coated metal part according to claim 23,
wherein the thermosetting resin is a silicone resin, and
wherein each second functional group is a compound, a chemical structure, or a derivative having at least one selected from the group consisting of platinum, palladium, ruthenium, and rhodium.

27. The resin-coated metal part according to claim 15,
wherein each second functional group is a compound, a chemical structure, or a derivative having at least one selected from the group consisting of a fluorescent compound and a phosphorescent compound.

28. A resin-sealed semiconductor device comprising:
the wiring member of claim 15; and
a semiconductor element electrically connected to the wiring lead,
wherein a portion of the wiring lead is externally exposed, and
wherein the semiconductor element is sealed with a resin within the surface region of the wiring lead covered by the organic coating.

29. A resin-coated metal part comprising:
a wiring member including:
a wiring lead composed of a metallic material; and
an organic coating disposed to cover a surface region of the wiring lead, the organic coating being composed of a plurality of self-assembled functional organic molecules; and
a thermosetting resin material adhered to a portion of the wiring member,
wherein each of the functional organic molecules has a chemical structure having a main chain, a first functional group, and a second functional group, the first functional group and the second functional group each being provided at a different end of the main chain, the first functional group being in a form for bonding to the wiring lead by any one or more of a metal bond, a hydrogen bond, and a coordinate bond by a metal complex, and the second functional group having a resin hardening property or a resin-hardening promoting property,
wherein each of the first functional groups has bonded to the wiring lead,
wherein the second functional group is a compound, a chemical structure, or a derivative having at least one selected from the group consisting of a vinyl group, an organohydrogensilane, a hydroxyl, an acid anhydride, a primary amine, and a secondary amine, and
wherein the thermosetting resin is a silicone resin or a silicone resin modified with at least either of an epoxy group and an alkoxysilyl group.
